(19) United States
(12) Patent Application Publication
(10) Pub. No.: US 2024/0199411 A1
(43) Pub. Date: Jun. 20, 2024

(54) VERTICALLY STACKED MEMS DEVICES AND CONTROLLER DEVICE

(71) Applicant: Qorvo US, Inc., Greensboro, NC (US)

(72) Inventors: Robertus Petrus Van Kampen, S-Hertogenbosch (NL); Roberto Gaddi, Rosmalen (NL); Paul Castillou, San Jose, CA (US); Lance Barron, Plano, TX (US); Julio C. Costa, Oak Ridge, NC (US); Jonathan Hale Hammond, Oak Ridge, NC (US); Mickael Renault, San Jose, CA (US)

(21) Appl. No.: 18/288,063

(22) PCT Filed: Apr. 29, 2022
(86) PCT No.: PCT/US2022/026971

§ 371 Date: Oct. 24, 2023

Related U.S. Application Data
(60) Provisional application No. 63/182,582, filed on Apr. 30, 2021.

(51) Int. Cl. B81B 7/00; B81C 1/00

(52) U.S. Cl. CPC B81B 7/0074; B81B 7/007; B81C 1/0023; B81C 1/00301; B81B 2201/01; B81B 2207/012; B81B 2207/07; B81B 2207/096; B81C 2203/0792

(57) ABSTRACT

Various arrangements for a microelectromechanical (MEMS) die and a controller die in vertically stacked structures are disclosed. The orientations of the MEMS die and the controller die vary in the various arrangements. In one embodiment, a backside surface of the MEMS die is operably connected to a frontside surface of the controller die. In another embodiment, a backside surface of the MEMS die is operably connected to a backside surface of the controller die. In another embodiment, a frontside surface of the MEMS die is operably connected to a backside surface of the controller die. In yet another embodiment, a frontside surface of the MEMS die is operably connected to a frontside surface of the controller die.

### CROSS-REFERENCE TO RELATED APPLICATIONS

This application claims the benefit of U.S. provisional patent application Ser. No. 63/182,582, filed Apr. 30, 2021, the disclosure of which is hereby incorporated herein by reference in its entirety.

### FIELD OF THE DISCLOSURE

The technology of the present disclosure relates to microelectronics packages and processes for making the same. More particularly, the technology of the present disclosure relates to microelectronics packages with vertically stacked structures that include a microelectromechanical systems (MEMS) device and a controller device.

### BACKGROUND

The wide utilization of cellular and wireless devices continues to drive the rapid development of radio frequency (RF) technologies. The RF technologies include MEMS devices that have one or more MEMS RF switches. The one or more MEMS RF switches route RF signals to and from various transmit/receive paths and/or circuit components. A controller device transmits control signals to a MEMS device that causes the one or more MEMS RF switches to open and close.

In some instances, the controller device and the MEMS device are discrete devices that are positioned in a horizontal side-by-side arrangement on the same circuit board, and the control signals are routed between the controller device and the MEMS device using the circuit board. However, this side-by-side arrangement can consume a large amount of area on the circuit board. Additionally, the lengths of the signal paths between the controller device and the one or more MEMS RF switches may be long, which can adversely impact the performance of the controller device and the MEMS device.

### SUMMARY

Example aspects of the present disclosure provide vertically stacked structures that include a MEMS die and a controller die. Various arrangements for the MEMS die and the controller die are disclosed. The orientations of the MEMS die and the controller die vary in the various arrangements. For example, in one embodiment, a backside surface of the MEMS die is operably connected to a frontside surface of the controller die. In another embodiment, a backside surface of the MEMS die is operably connected to a backside surface of the controller die. In another embodiment, a frontside surface of the MEMS die is operably connected to a backside surface of the controller die. In yet another embodiment, a frontside surface of the MEMS die is operably connected to a frontside surface of the controller die.

One or more of the arrangements reduce or minimize RF loss and coupling between the MEMS die and the controller die. For example, the arrangement that physically and operably (e.g., electrically) connects the backside surface of the MEMS die to the frontside surface of the controller die operably separates MEMS circuitry in the MEMS die, such as one or more MEMS RF switches, from controller circuitry in the controller die (e.g., FIG. 1). This arrangement reduces capacitive coupling between the MEMS die and the controller die. Accordingly, the arrangement experiences an enhanced RF linearity.

One or more of the arrangements shield signal lines or isolate signal lines that transmit RF signals from the controller voltage boost circuits. Additionally or alternatively, one or more arrangements shields or isolates the RF signals from a silicon substrate in the MEMS device (e.g., a high resistivity silicon substrate). For example, the arrangement that physically and operably connects the backside surface of the MEMS die to the frontside surface of the controller die shields the RF signals from a silicon substrate in the MEMS device (e.g., FIG. 1).

The various arrangements of the vertically stacked structures reduce the footprint of the MEMS die and the controller die and/or use less material compared to the horizontal side-by-side arrangements of the MEMS die and the controller die. The final packages have a smaller package size. The final packages can also achieve better mechanical stability due to their smaller size.

Additionally or alternatively, one or more of the arrangements separate the RF domain (e.g., high frequency domain) from the low frequency domain. The low frequency domain includes power signals that are received by the MEMS die and the controller die, control signals that are transmitted from the controller die to the MEMS die, and/or input and output (I/O) signals that are received by the controller die. Unlike signals in the high frequency domain, signals in the low frequency domain can be routed or transmitted through high resistivity substrates without significant problems. In one or more of the arrangements, the RF domain remains at a surface of the vertically stacked structure. For example, the RF signals remain at a frontside surface of the MEMS die in the embodiment shown in FIG. 1. The RF signals are not routed or transmitted through the substrate of the MEMS die nor the substrate of the controller die, thereby avoiding potential increased losses and linearity degradation.

In one aspect, a vertically stacked structure includes a MEMS die operably connected to a controller die using a first electrical connector. The controller die includes controller circuitry formed in and over a first substrate, and the controller circuitry is operably connected to the first electrical connector. The MEMS die includes MEMS circuitry formed in or over a second substrate, and the MEMS circuitry is operably connected to the first electrical connector. The first electrical connector is operable to transmit a control signal from the controller circuitry to the MEMS circuitry. A second electrical connector is operably connected to the MEMS circuitry. The second electrical connector is operable to transmit an RF signal from the MEMS circuitry and out of the vertically stacked structure, where the RF signal is not routed through the first substrate of the controller die or the second substrate of the MEMS die. The RF signal remains at a frontside surface of the MEMS die.

In another aspect, a vertically stacked structure includes a MEMS die and a controller die. A backside surface of the MEMS die is operably connected to a frontside surface of the controller die through a first electrical connector. The controller die includes a first substrate and controller circuitry. The controller circuitry is operably connected to the first electrical connector to enable the controller circuitry to transmit control signal to the first electrical connector. The MEMS die includes a second substrate and one or more MEMS RF switches. The one or more MEMS RF switches are operably connected to the first electrical connector to enable the one or more MEMS RF switches to receive the control signal. A dam structure is formed around a space between the backside surface of the MEMS die and the frontside surface of the controller die. The dam structure surrounds a perimeter of the space to form a closed region that produces an air pocket region when the MEMS die is operably connected to the controller die. A second electrical connector is operably connected to the one or more MEMS RF switches. The second electrical connector is operable to transmit an RF signal from the one or more MEMS RF switches and out of the vertically stacked structure without transmitting the RF signals through the first substrate of the controller die or the second substrate of the MEMS die. The RF signal remains at a frontside surface of the MEMS die.

In yet another aspect, a method includes forming a dam structure over a backside surface of a MEMS die, where the dam structure extends around a perimeter of a space that will not be encapsulated (e.g., a space where the encapsulation material is omitted). The backside surface of the MEMS die is physically and operably connected to a frontside surface of a controller die using a first electrical connector. The controller die includes a first substrate and controller circuitry. The controller circuitry is operably connected to the first electrical connector to enable the first electrical connector to transmit a control signal to the MEMS die. The MEMS die comprises a second substrate and one or more MEMS RF switches. The one or more MEMS RF switches are operably connected to the first electrical connector to enable the one or more MEMS RF switches to receive the control signal from the first electrical connector. The dam structure surrounds a space between the frontside surface of the controller die and the backside surface of the MEMS die to create an air pocket region. An encapsulation layer is formed over a backside surface of the controller layer and over portions of the backside surface of the MEMS die. The one or more MEMS RF switches are operably connected to a second electrical connector to enable the second electrical connector to transmit an RF signal from at least one of the one or more MEMS RF switches and out of the vertically stacked structure without transmitting the RF signal through the first substrate of the controller die or the second substrate of the MEMS die. The RF signal remains at a frontside surface of the MEMS die.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWINGS

The accompanying drawing figures incorporated in and forming a part of this specification illustrate several aspects of the disclosure and, together with the description, serve to explain the principles of the disclosure.

FIG. 1 illustrates a vertical cross section of a first vertically stacked structure that includes a controller die and a MEMS die in accordance with embodiments of the disclosure;

FIG. 2 illustrates a vertical cross section of an example controller wafer in accordance with embodiments of the disclosure;

FIG. 3 illustrates a vertical cross section of the controller wafer shown in FIG. 2 with the addition of first and second polymer layers and a first Re-Distribution Layer (RDL) in accordance with embodiments of the disclosure;

FIG. 4 illustrates a vertical cross section of the controller wafer shown in FIG. 3 with the addition of first electrical connectors that are formed on the first RDL in accordance with embodiments of the disclosure;

FIG. 5 illustrates a vertical cross section of an example MEMS wafer in accordance with embodiments of the disclosure;

FIG. 6 illustrates a vertical cross section of the MEMS wafer shown in FIG. 5 with the addition of a third polymer layer in accordance with embodiments of the disclosure;

FIG. 7 illustrates a vertical cross section of the MEMS wafer shown in FIG. 6 with the addition of a second RDL in accordance with embodiments of the disclosure;

FIG. 8 illustrates a vertical cross section of the MEMS wafer shown in FIG. 7 with the addition of a fourth polymer layer in accordance with embodiments of the disclosure;

FIG. 9 illustrates a vertical cross section of the MEMS wafer shown in FIG. 8 with the addition of a first under bump metallization (UBM) layer in accordance with embodiments of the disclosure;

FIG. 10 illustrates a vertical cross section of the MEMS wafer shown in FIG. 9 with the addition of a film and a carrier wafer in accordance with embodiments of the disclosure;

FIG. 11 illustrates a vertical cross section of the structure shown in FIG. 10 after the second substrate of the MEMS wafer is thinned in accordance with embodiments of the disclosure;

FIG. 12 illustrates a vertical cross section of the structure shown in FIG. 11 with the addition of a fourth dielectric layer in accordance with embodiments of the disclosure;

FIG. 13 illustrates a vertical cross section of the structure shown in FIG. 12 with the addition of a Through Silicon Via (TSV) that is formed in the fourth dielectric layer and the second substrate of the MEMS wafer in accordance with embodiments of the disclosure;

FIG. 14 illustrates a vertical cross section of the structure shown in FIG. 13 with the addition of a fifth dielectric layer in accordance with embodiments of the disclosure;

FIG. 15 illustrates a vertical cross section of the structure shown in FIG. 14 with the addition of a third RDL in accordance with embodiments of the disclosure;

FIG. 16 illustrates a vertical cross section of the structure shown in FIG. 15 with the addition of a fifth polymer layer in accordance with embodiments of the disclosure;

FIG. 17 illustrates a vertical cross section of the structure shown in FIG. 16 with the addition of a second UBM layer in accordance with embodiments of the disclosure;

FIG. 18A illustrates a vertical cross section of the structure shown in FIG. 17 with the addition of a dam structure in accordance with embodiments of the disclosure;

FIG. 18B illustrates a top view of the dam structure shown in FIG. 18A in accordance with embodiments of the disclosure;

FIG. 19 illustrates a vertical cross section of the structure shown in FIG. 4 attached to the structure shown in FIG. 18 in accordance with embodiments of the disclosure;

FIG. 20 illustrates a vertical cross section of the controller wafer shown in FIG. 4 operably connected to the structure shown in FIG. 18 with the addition of an encapsulation in accordance with embodiments of the disclosure;

FIG. 21 illustrates a vertical cross section of a vertically stacked structure after the film and the carrier wafer shown in FIG. 20 are removed in accordance with embodiments of the disclosure;

FIG. 22 illustrates a vertical cross section of the vertically stacked structure shown in FIG. 21 with the addition of second electrical connectors in accordance with embodiments of the disclosure;

FIG. 23 illustrates example sections in the first version of the first vertically stacked structure shown in FIG. 22 in accordance with embodiments of the disclosure;

FIG. 24 illustrates a vertical cross section of the controller wafer shown in FIG. 4 attached to the structure shown in FIG. 17 in accordance with embodiments of the disclosure;

FIG. 25 illustrates a vertical cross section of the structure operably connected to the structure as shown in FIG. 24 with the addition of the encapsulation layer in accordance with embodiments of the disclosure;

FIG. 26 illustrates a vertical cross section of a vertically stacked structure after the film and the carrier wafer shown in FIG. 25 are removed in accordance with embodiments of the disclosure;

FIG. 27 illustrates a vertical cross section of a second version of the first vertically stacked structure shown in FIG. 1 with the addition of second electrical connectors in accordance with embodiments of the disclosure;

FIG. 28 illustrates a vertical cross section of a second vertically stacked structure that includes the controller die and the MEMS die shown in FIG. 1 in accordance with embodiments of the disclosure;

FIG. 29A illustrates a vertical cross section of a third vertically stacked structure that includes the controller die and the MEMS die shown in FIG. 1 in accordance with embodiments of the disclosure;

FIG. 29B illustrates a vertical cross section of a fourth vertically stacked structure that includes the controller die and the MEMS die shown in FIG. 1 in accordance with embodiments of the disclosure;

FIG. 30A illustrates a vertical cross section of a fifth vertically stacked structure that includes the controller die and the MEMS die shown in FIG. 1 in accordance with embodiments of the disclosure;

FIG. 30B illustrates a vertical cross section of a sixth vertically stacked structure that includes the controller die and the MEMS die shown in FIG. 1 in accordance with embodiments of the disclosure;

FIG. 31A illustrates a vertical cross section of a seventh vertically stacked structure that includes the controller die and the MEMS die shown in FIG. 1 in accordance with embodiments of the disclosure;

FIG. 31B illustrates a vertical cross section of an eighth vertically stacked structure that includes the controller die and the MEMS die shown in FIG. 1 in accordance with embodiments of the disclosure;

FIG. 32 illustrates a vertical cross section of a ninth vertically stacked structure that includes the controller die shown in FIG. 1 and an alternate MEMS die in accordance with embodiments of the disclosure; and

FIG. 33 illustrates a vertical cross section of an example of the alternate MEMS die shown in FIG. 32 in accordance with embodiments of the disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected”, “operably connected”, “coupled” or “operably coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

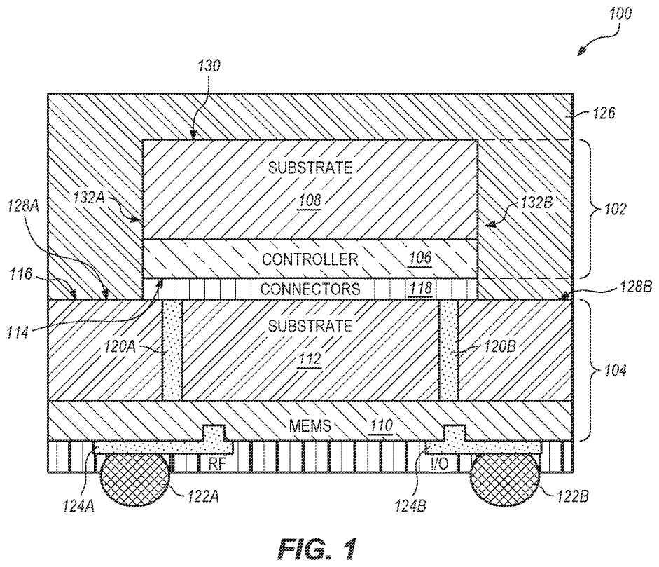

FIG. 1 illustrates a first vertically stacked structure 100 that includes a controller die 102 and a MEMS die 104 in accordance with embodiments of the disclosure. The controller die 102 includes controller circuitry 106 formed in and/or over a first substrate 108. The controller circuitry 106 includes any suitable type of circuitry, such as n-type transistors, p-type transistors, resistors, capacitors, conductive layers (e.g., metal layers) that form interconnects, vias, contact pads, and dielectric layers. In one embodiment, the controller circuitry 106 is fabricated using complementary-metal-oxide semiconductor (CMOS) fabrication processes. The fist substrate 108 can be any suitable type of substrate including, but not limited to, a silicon substrate (e.g., a low resistivity or a high resistivity silicon substrate) and a dielectric substrate (e.g., a silicon nitride substrate).

The MEMS die 104 includes MEMS circuitry 110 formed in and/or over a second substrate 112. The MEMS circuitry 110 includes any suitable type of circuitry, including one or more MEMS RF switches, resistors, and conductive layers (e.g., metal layers) that form signal lines and contact pads. The second substrate 112 may be any suitable type of substrate including, but not limited to, a silicon substrate (e.g., a high resistivity silicon substrate), a high resistivity substrate, and a dielectric substrate (e.g., a silicon nitride substrate).

A frontside surface 130 of the controller die 102 is operably connected to a backside surface 116 of the MEMS die 104 using a connector layer 118. The connector layer 118 includes one or more electrical connectors that operably (e.g., electrically) connect the controller die 102 to the MEMS die 104. Example electrical connectors include, but are not limited to, solder balls and copper pillars.

A first through-silicon via (TSV) 120A and a second TSV 120B are formed through the second substrate 112. Although FIG. 1 shows two TSVs 120A, 120B, the MEMS die 104 may include any number of TSVs. The first TSV 120A and the second TSV 120B are operable to transmit signals to and between the controller die 102 and the MEMS die 104. In one embodiment, the first TSV 120A is operable to transmit power signals, such as voltage and ground signals, from the MEMS die 104 to the controller die 102. The second TSV 120B is operable to transmit control signals and I/O signals to and between the MEMS die 104 and the controller die 102. For example, the second TSV 120B can transmit control signals from the controller circuitry 106 to one or more MEMS RF switches in the MEMS circuitry 110 to open or close the one or more MEMS RF switches.

RF signals are input and output from the MEMS circuitry 110 to another electronic component, such as an antenna, using first electrical connector 122A and first contact pad 124A. I/O signals are input and output to the MEMS circuitry 110 and/or to the controller circuitry 106 using second electrical connector 122B and second contact pad 124B. In FIG. 1, the first and the second electrical connectors 122A, 122B are shown as solder balls, but other embodiments can use a different type of electrical connector.

An encapsulation layer 126 is formed over the controller die 102 and the MEMS die 104. In one embodiment, the encapsulation layer 126 is formed using an overmolding process. The encapsulation layer 126 can contact the backside surface 130 of the controller die 102, the side edges 132A, 132B of the controller die 102, and exposed portions 128A, 128B of the backside surface 116 of the MEMS die 104. The encapsulation layer 126 protects the controller die 102 and the exposed portions 128A, 128B of the backside surface 116 of the MEMS die 104 from physical damage, corrosion, and the operating environment (e.g., dust, moisture, dirt, solvents).

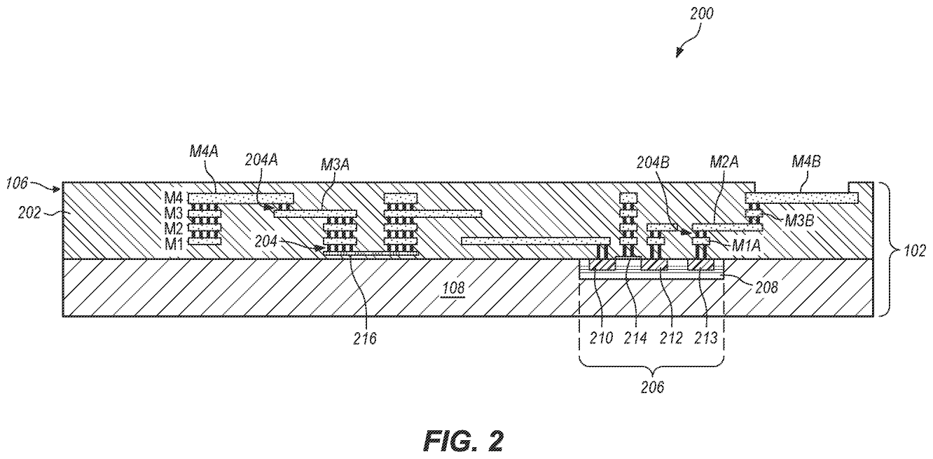

Various fabrication processes may be used to fabricate the first vertically stacked structure 100 shown in FIG. 1. FIGS. 2-22 depict one example method of fabricating the first vertically stacked structure 100. FIG. 2 illustrates an example controller wafer 200 in accordance with embodiments of the disclosure. The example controller wafer 200 includes controller circuitry 106 formed in and/or over the first substrate 108. The controller circuitry 106 includes four conductive layers (e.g., metal layers) M1, M2, M3, M4 that are formed in one or more first dielectric layers 202. The conductive layers M1, M2, M3, M4 may be used to transmit signals between components (e.g., resistors, transistors, diodes, capacitors) within the controller circuitry 106 and to transmit signals into and out of the controller circuitry 106. Other embodiments can include any number of conductive layers.

Conductive vias (e.g., metal vias) 204 operably (e.g., electrically) connect select conductive layers M1, M2, M3, M4 to other conductive layers M1, M2, M3, M4. For example, conductive via 204A operably connects conductive layer M3A to conductive layer M4A. Similarly, conductive via 204B operably connects conductive layer M1A to conductive layer M2A. In the example embodiment, the conductive layer M4B forms a conductive contact. Other embodiments may include any number of conductive layers.

The controller circuitry 106 further includes a transistor 206. The transistor 206 is formed in a well region 208 that is formed in the first substrate 108. The well region 208 is of a first conductivity type (e.g., p-type conductivity), and includes source/drain regions (210, 212) of a second conductivity type (e.g., n-type conductivity). Thus, the transistor 206 may be an n-type transistor or a p-type transistor. A gate contact 214 is formed as a conductive element positioned between the source/drain regions (210, 212). Terminal contact 210 and terminal contact 212 provide electrical connections to the source/drain regions and contact 213 provides an electrical connection to the well region of the transistor 206. Although only one transistor 206 is shown in FIG. 2, the controller circuitry 106 may include any number of transistors.

The controller circuitry 106 includes a conductive element 216. In one embodiment, the conductive element 216 functions as a resistor. The conductive element 216 can be made of any suitable material, such as polysilicon. Although only one conductive element 216 is shown in FIG. 2, the controller circuitry 106 may include any number of conductive elements that can be used for any function.

Other embodiments of the controller wafer 200 can include fewer, more, or different types of controller circuitry 106. For example, a controller wafer 200 may include one or more capacitors, one or more inductors, one or more diodes, and/or other types of active and passive devices.

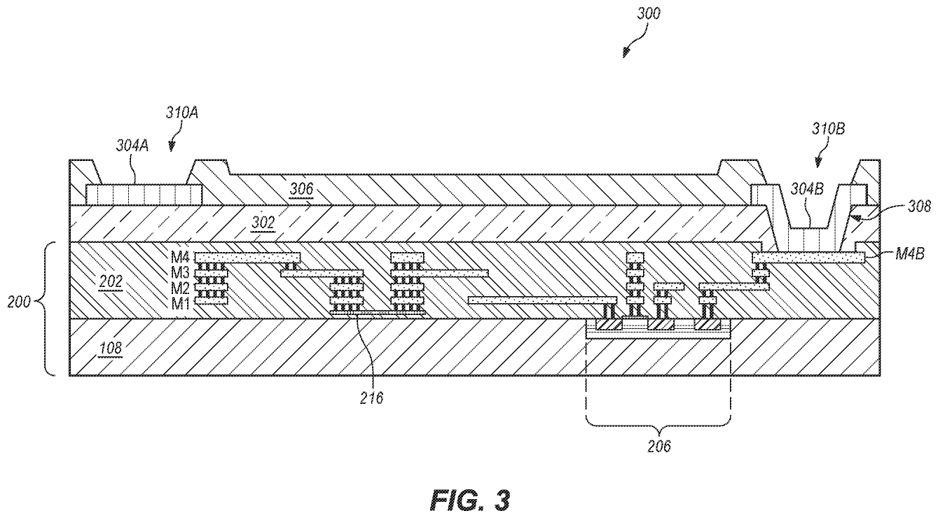

FIG. 3 illustrates the controller wafer 200 shown in FIG. 2 with the addition of a first polymer layer 302, a first Re-Distribution Layer (RDL) 304A, 304B, and a second polymer layer 306 in accordance with embodiments of the disclosure. In one embodiment, the first and the second polymer layers 302, 306 are polyimide layers and the first RDL 304A, 304B is made of a conductive material, such as metal.

The first polymer layer 302 is formed over the controller wafer 200. In non-limiting nonexclusive examples, the first polymer layer 302 may be deposited over the controller wafer 200, or the first polymer layer 302 can be a laminate film that is laminated over the controller wafer 200. The first polymer layer 302 is then patterned to produce an opening 308 that exposes a portion of the conductive layer M4B. To pattern the first polymer layer 302, a photoresist masking layer (not shown) may be formed over the first polymer layer 302 and exposed to a developer to form an opening (not shown) in the photoresist masking layer where the opening 308 in the first polymer layer 302 will be formed. A portion of the first polymer layer 302 that is exposed in the opening in the photoresist masking layer is removed to form the opening 308 in the first polymer layer 302. The photoresist masking layer is then removed. In certain embodiments, the first polymer layer 302 is photosensitive so a photoresist masking layer is not used. The portion of the first polymer layer 302 is exposed through a mask and then developed to create the opening 308.

The first RDL 304A is formed over a portion of the first polymer layer 302 and the first RDL 304B is formed in the opening 308 and over portions of the first polymer layer 302. In a non-limiting nonexclusive example, the first RDL 304A, 304B is made of metal (e.g., copper). To form the first RDL 304A, 304B, a seed layer can be formed on the first polymer layer 302 and on the exposed portion of the conductive layer M4B and plated with additional RDL material to produce the first RDL 304A, 304B.

The second polymer layer 306 is formed over the first polymer layer 302 and the first RDL 304A, 306B. In a non-limiting nonexclusive example, the second polymer layer 306 is a polyimide layer. Formation and patterning of the second polymer layer 306 can be similar to the formation and patterning of the first polymer layer 302. As shown, the second polymer layer 306 is patterned to produce openings 310A, 310B in the second polymer layer 306 to expose portions of the first RDL 304A, 304B, respectively.

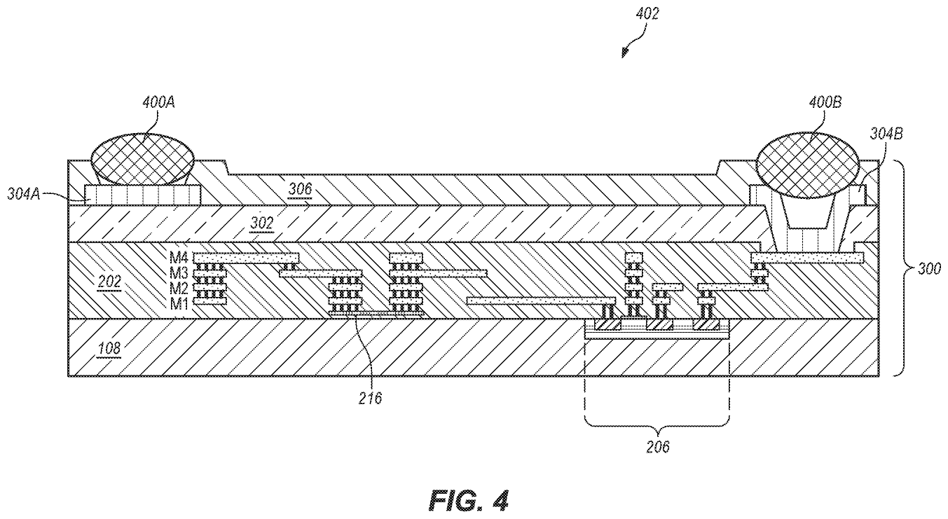

FIG. 4 illustrates the controller wafer 300 shown in FIG. 3 with the addition of first electrical connectors 400A, 400B that are formed on the first RDL 304A, 304B, respectively, in accordance with embodiments of the disclosure. In FIG. 4, the first electrical connectors 400A, 400B are depicted as solder balls. However, the first electrical connectors 400A, 400B may be any suitable type of electrical connectors (e.g. copper pillars). With the formation of the first electrical connectors 400A, 400B, the structure 402 is formed.

In certain embodiments, an under bump metallization (UBM) layer (not shown) is formed over the first RDL 304A, 304B before the first electrical connectors 400A, 400B are formed. The UBM layer can improve the bonding strength of the first electrical connectors 400A, 400B to the first RDL 304A, 304B.

The first electrical connector 400B is an electrically active electrical connection because the first electrical connector 400B is operably (e.g., electrically) connected to the first RDL 304B, which is operably (e.g., electrically) connected to the transistor 206 through conductive layers M4-M1. The first RDL 304A is a dummy pad and the first electrical connector 400A is dummy connector because the first RDL 304A is not operably connected to any electrical circuits or components in the controller circuitry.

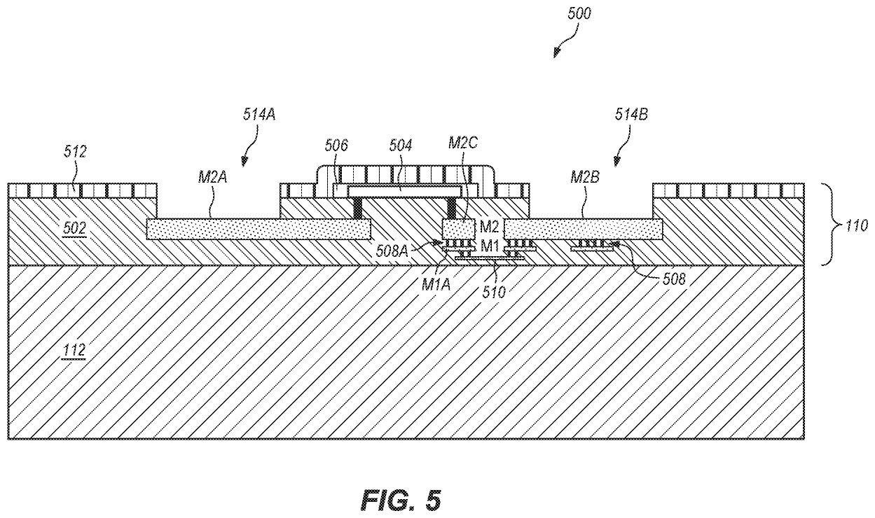

FIG. 5 illustrates an example MEMS wafer 500 in accordance with embodiments of the disclosure. The example MEMS wafer 500 includes MEMS circuitry 110 formed in and/or over the second substrate 112. The example MEMS circuitry 110 includes two conductive layers (e.g., metal layers) M1, M2 that are formed in one or more second dielectric layers 502. The conductive layers M1, M2 may be used to transmit signals to, from, and between one or more MEMS RF switches 504 (e.g., a switch array) in the MEMS circuitry 110, and to transmit signals into and out of the MEMS circuitry 110. The one or more MEMS RF switches 504 are formed in a MEMS cavity 506. In FIG. 5, the conductive layers M2A and M2B form conductive contacts. Other embodiments may include any number of conductive layers.

Conductive vias (e.g., metal vias) 508 operably connect select conductive layers M1, M2 to other conductive layers M1, M2. For example, conductive via 508A operably connects conductive layer M1 A to conductive layer M2C.

The MEMS circuitry 110 includes conductive elements 510. In a non-limiting nonexclusive example, the conductive element 510 functions as a resistor. The conductive element 510 can be made of any suitable material, such as polysilicon. Although only one conductive element 510 is shown in FIG. 5, the MEMS circuitry 110 may include any number of conductive elements that can be used for any function.

A third dielectric layer 512 is formed over the one or more second dielectric layers 502. In a non-limiting nonexclusive example, the one or more second dielectric layers 502 are oxide layers and the third dielectric layer 512 is a nitride layer or a combination of oxide and nitride layers. In FIG. 5, the MEMS cavity 506 is encapsulated by the one or more second dielectric layers 502 and the third dielectric layer 512. In other embodiments, the MEMS cavity 506 may be encapsulated by one dielectric layer.

The one or more second dielectric layers 502 and the third dielectric layer 512 are patterned to produce opening 514A that exposes a portion of the conductive layer M2A and to produce opening 514B that exposes a portion of the conductive layer M2B. To pattern the one or more second dielectric layers 502 and the third dielectric layer 512, a photoresist masking layer (not shown) may be formed over the third dielectric layer 512 and exposed to a developer to form openings (not shown) in the photoresist masking layer where the openings 514A, 514B will be formed. Portions of the one or more second dielectric layers 502 and the third dielectric layer 512 aligned with the openings in the photoresist masking layer are removed to form the openings 514A, 514B that expose the portions of the conductive layers M2A and M2B, respectively. The photoresist masking layer is then removed.

In FIG. 5, the conductive layer M2A is operably connected to the one or more MEMS RF switches 504. As such, the conductive layer M2A will be used to transmit RF signals out of the completed first vertically stacked structure 100 shown in FIG. 1. The conductive layer M2B will be used to transmit control signals to the one or more MEMS RF switches 504 in the completed first vertically stacked structure 100 (FIG. 1).

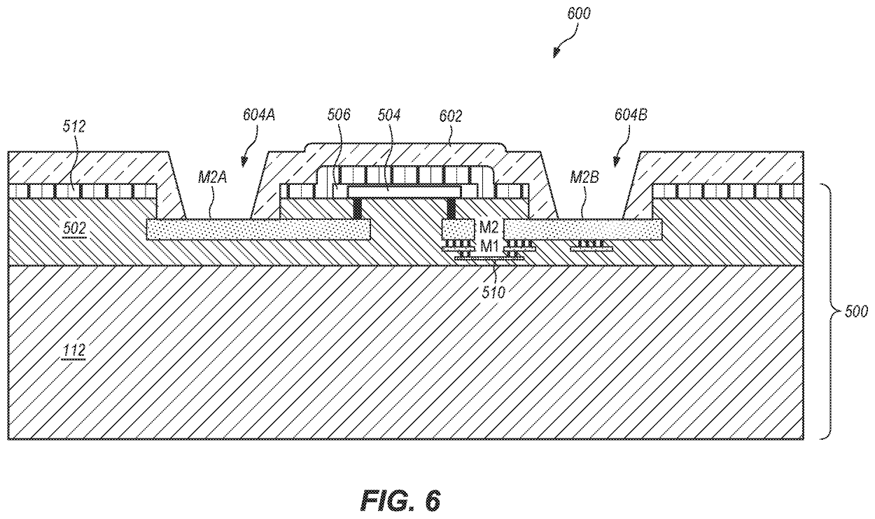

FIG. 6 illustrates the MEMS wafer 500 shown in FIG. 5 with the addition of a third polymer layer 602 in accordance with embodiments of the disclosure. In a non-limiting nonexclusive example, the third polymer layer 602 is a polyimide layer. Formation and patterning of the third polymer layer 602 can be similar to the formation and patterning of the first polymer layer 302 of FIG. 3. As shown, the third polymer layer 602 is patterned to produce openings 604A, 604B that expose portions of the conductive layers M2A, M2B, respectively.

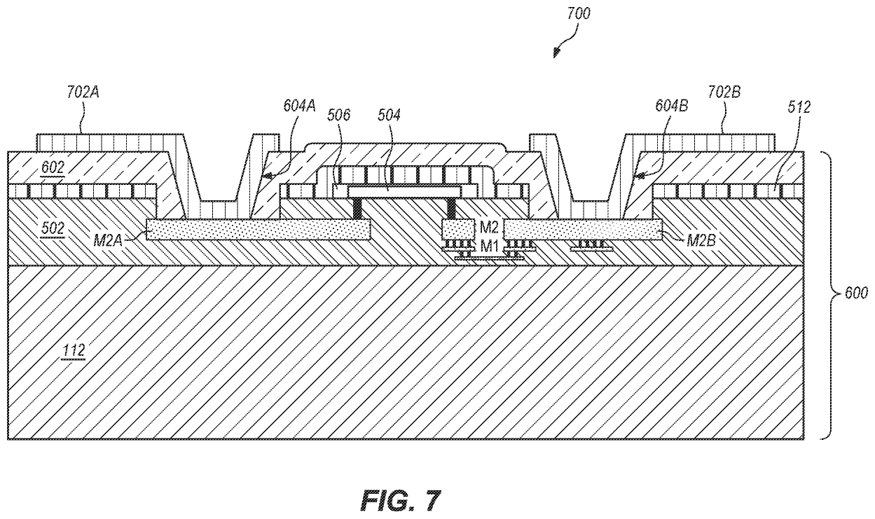

FIG. 7 illustrates the MEMS wafer 600 shown in FIG. 6 with the addition of a second RDL 702A, 702B in accordance with embodiments of the disclosure. The second RDL 702A, 702B is formed over portions of the third polymer layer 602 and in the openings 604A, 604B to contact the conductive layers M2A, M2B. Formation of the second RDL 702A, 702B may be similar to the formation of the first RDL 304A, 304B of FIG. 3.

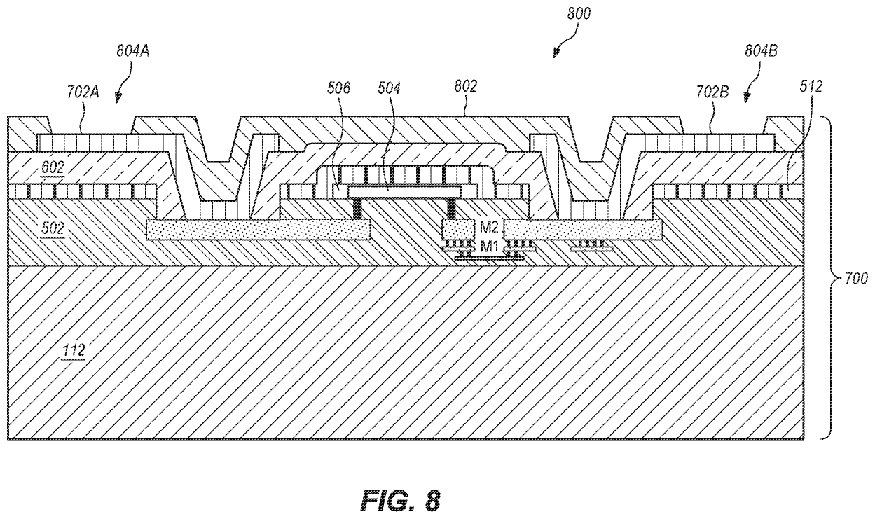

FIG. 8 illustrates the MEMS wafer 700 shown in FIG. 7 with the addition of a fourth polymer layer 802 in accordance with embodiments of the disclosure. In a non-limiting nonexclusive example, the fourth polymer layer 802 is a polyimide layer. Formation and patterning of the fourth polymer layer 802 can be similar to the formation and patterning of the first polymer layer 302 of FIG. 3. As shown, the fourth polymer layer 802 is patterned to produce openings 804A, 804B that expose portions of the second RDL 702A, 702B, respectively.

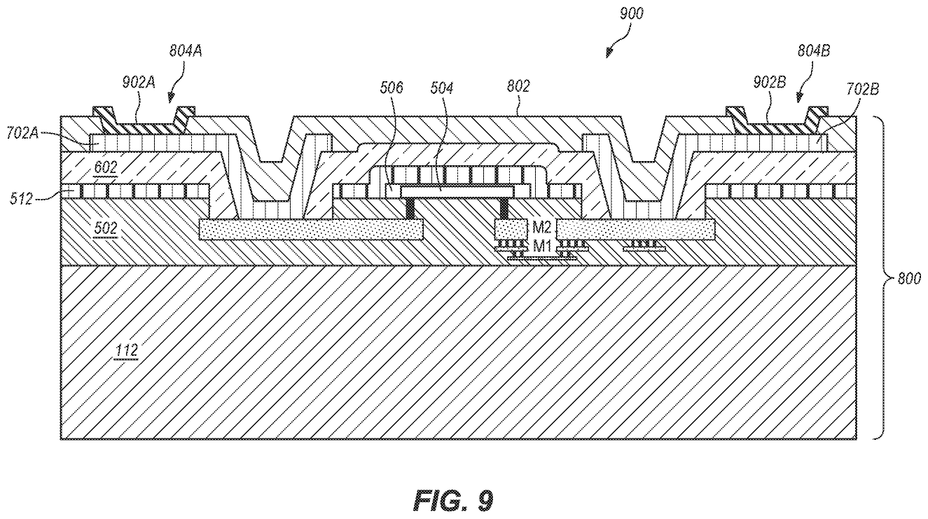

FIG. 9 illustrates the MEMS wafer 800 shown in FIG. 8 with the addition of a first UBM layer 902A, 902B in accordance with embodiments of the disclosure. In a non-limiting nonexclusive example, the first UBM layer 902A, 902B is a metal layer. The first UBM layer 902A, 902B may be formed on the second RDL 702A, 702B, respectively, by plating the first UBM layer 902A on the second RDL 702A that is exposed in the opening 804A and on portions of the fourth polymer layer 802, and by plating the first UBM layer 902B on the second RDL 702B that is exposed in the opening 804B and on portions of the fourth polymer layer 802. In certain embodiments, the first UBM layer 902A, 902B may be omitted.

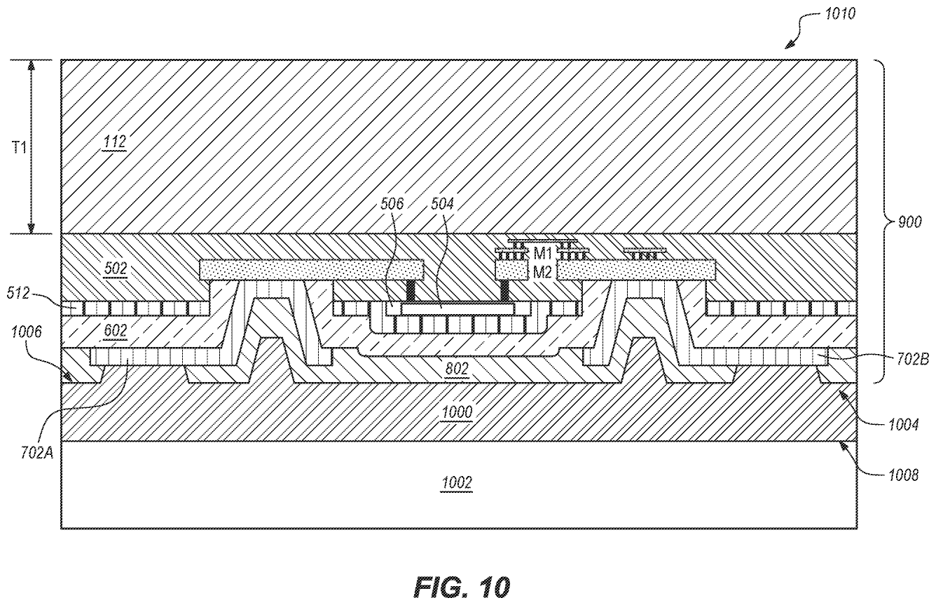

FIG. 10 illustrates the MEMS wafer 900 shown in FIG. 9 with the addition of a film 1000 and a carrier wafer 1002 in accordance with embodiments of the disclosure. The MEMS wafer 900 is flipped over onto the film 1000 such that the frontside 1004 of the MEMS wafer 900 is attached to a first surface 1006 of the film 1000. The carrier wafer 1002 is attached to a second surface 1008 of the film 1000. In non-limiting nonexclusive examples, the film 1000 is a polymer-based adhesive and the carrier wafer 1002 is made of glass, quartz, or silicon.

The MEMS wafer 900, the film 1000, and the carrier wafer 1002 form a structure 1010 that enables a thinning process to be performed on the second substrate 112. The film 1000 and the carrier wafer 1002 support the MEMS wafer 900 during the thinning process.

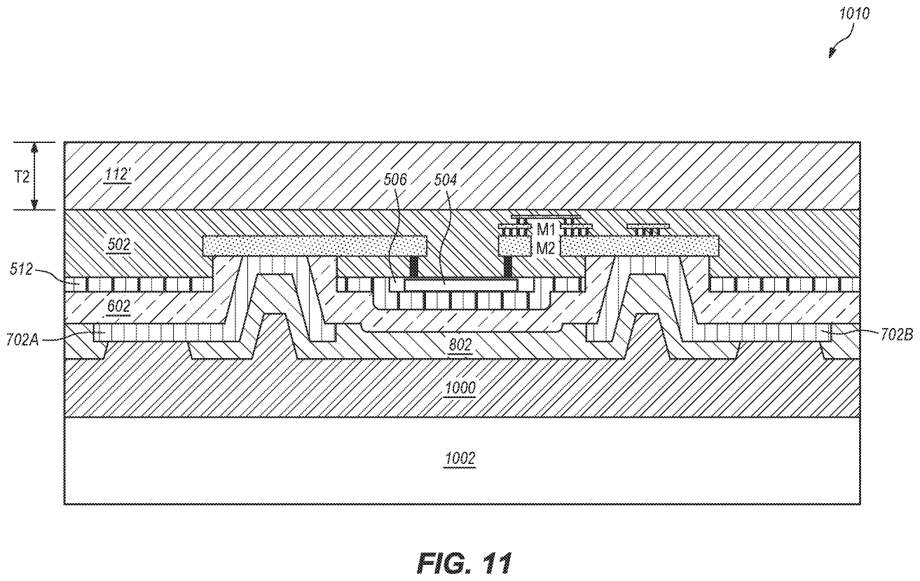

FIG. 11 illustrates the structure 1010 shown in FIG. 10 after the second substrate 112 of the MEMS wafer is thinned in accordance with embodiments of the disclosure. In a non-limiting nonexclusive example, the second substrate 112 has an initial thickness T1 (FIG. 10) of approximately seven hundred and fifty (750) micrometers. The second substrate 112 is thinned to a thickness T2 of approximately twenty-five (25) to seventy-five (75) micrometers. For example, the thickness T2 of the second substrate 112′ is approximately fifty (50) micrometers in one embodiment. Any suitable thinning process can be used to thin the second substrate 112. For example, the second substrate 112 may be thinned using a mechanical grinding process or a chemical mechanical polishing (CMP) process.

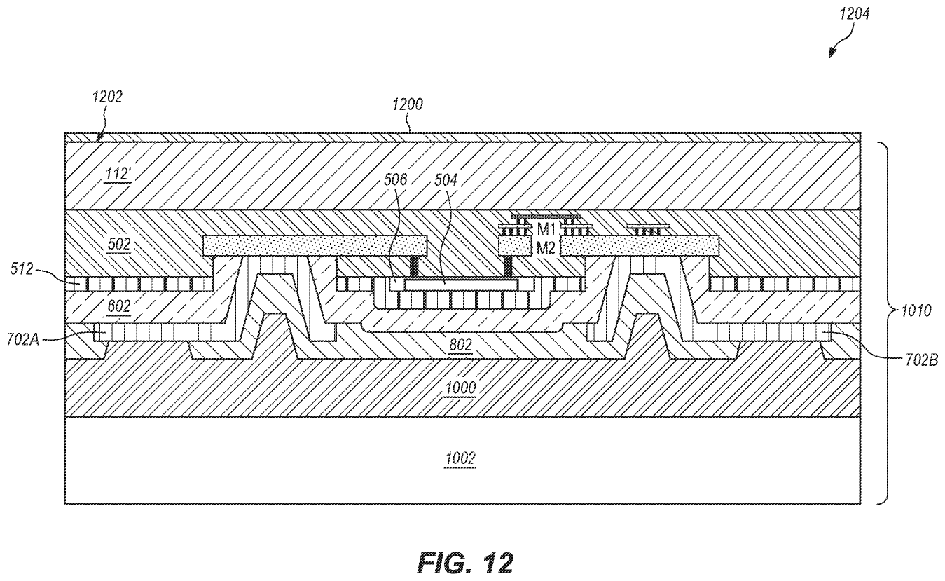

FIG. 12 illustrates the structure 1010 shown in FIG. 11 with the addition of a fourth dielectric layer 1200 in accordance with embodiments of the disclosure. The fourth dielectric layer 1200 is formed over a backside surface 1202 of the second substrate 112′. In a non-limiting non-exclusive example, the fourth dielectric layer 1200 is formed using a low-temperature oxide process.

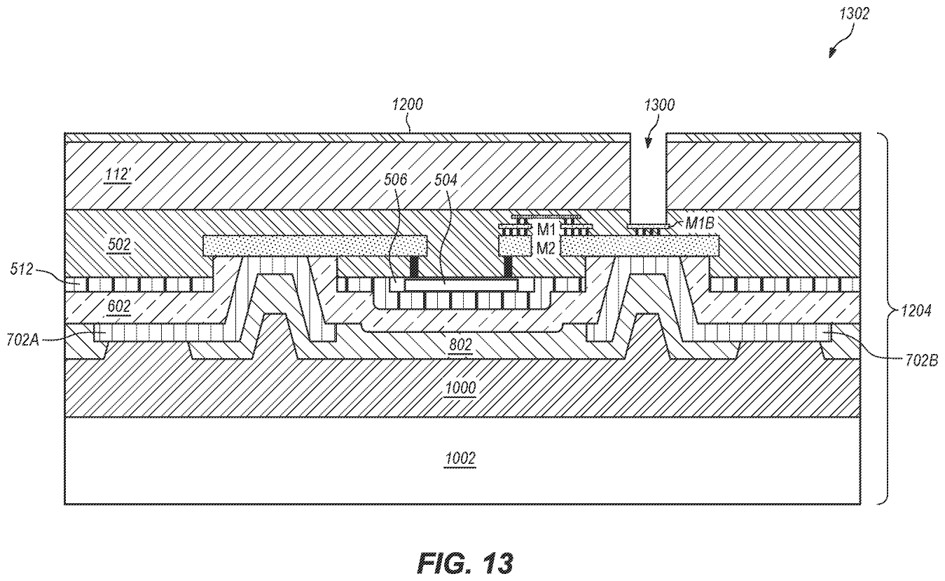

FIG. 13 illustrates the structure 1204 shown in FIG. 12 with the addition of a TSV 1300 that is formed in the fourth dielectric layer 1200 and the second substrate 112′ of the MEMS wafer in accordance with embodiments of the disclosure. The TSV 1300 may be formed by etching the fourth dielectric layer 1200, the second substrate 112′, and a portion of the one or more second dielectric layers 502. The TSV 1300 is formed to expose a portion of the conductive layer M1 B.

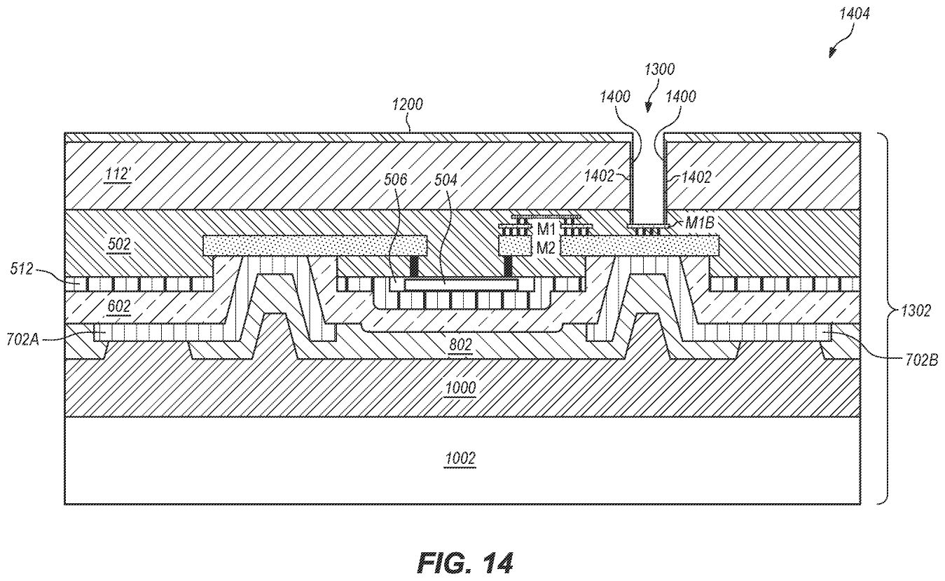

FIG. 14 illustrates the structure 1302 shown in FIG. 13 with the addition of a fifth dielectric layer 1400 in accordance with embodiments of the disclosure. In a non-limiting nonexclusive example, the fifth dielectric layer 1400 is formed by sputtering oxide over the fourth dielectric layer 1200, the sidewalls 1402 of the TSV 1300, and the exposed portion of the conductive layer M1 B. The oxide increases a thickness of the fourth dielectric layer 1200 and forms an oxide coating over the sidewalls 1402 and the exposed portion of the conductive layer M1 B. An etch process is then performed to thin the fourth dielectric layer 1200 and to remove the oxide coating from the exposed portion of the conductive layer M1 B. The fifth dielectric layer 1400 (e.g., the oxide coating on the sidewalls 1402) is not thinned substantially by the etch process because the sidewalls 1402 of the TSV 1300 are vertical surfaces.

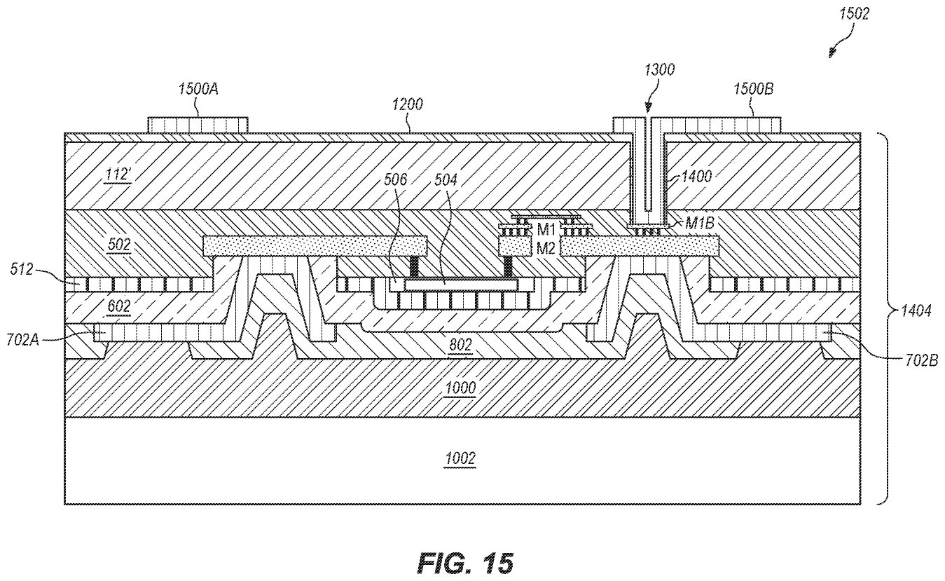

FIG. 15 illustrates the structure 1404 shown in FIG. 14 with the addition of a third RDL 1500A, 1500B in accordance with embodiments of the disclosure. The third RDL 1500A, 1500B can be formed in a similar process that is used to form the first RDL 304A, 304B. The third RDL 1500A is formed over a surface of the fourth dielectric layer 1200. The third RDL 1500B is formed over a surface of the fourth dielectric layer 1200 and over the fifth dielectric layer 1400 in the TSV 1300. The fifth dielectric layer 1400 prevents the third RDL 1500B from contacting the second substrate 112′. When the third RDL 1500B contacts the second substrate 112′, signals transmitted by the third RDL 1500B can interact electrically with the second substrate 112′ when the second substrate 112′ is an electrically active substrate (e.g., a high resistivity silicon substrate). The third RDL 1500B is also formed over the conductive layer M1 B to electrically connect the conductive layer M1 B to the third RDL 1500B.

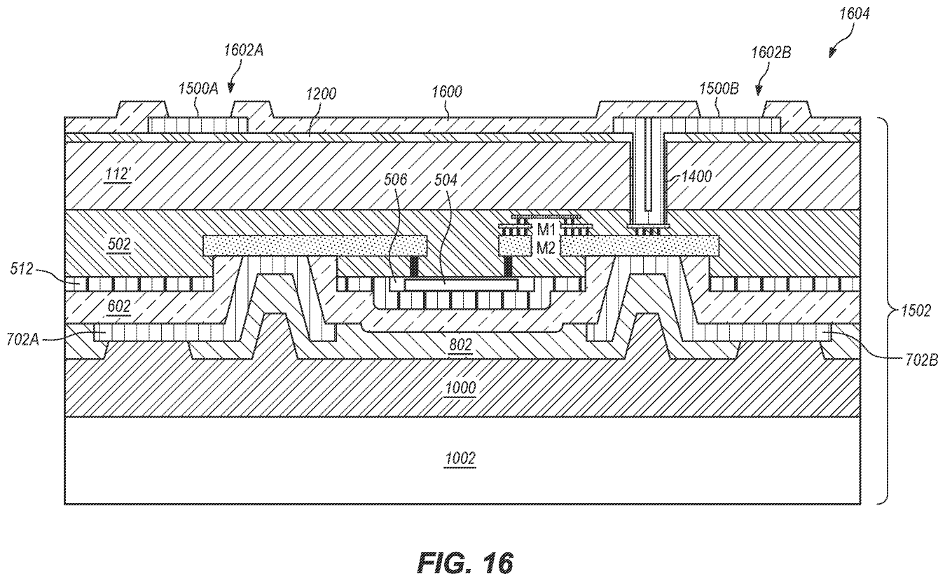

FIG. 16 illustrates the structure 1502 shown in FIG. 15 with the addition of a fifth polymer layer 1600 in accordance with embodiments of the disclosure. The fifth polymer layer 1600 is formed over the structure 1502. In a non-limiting nonexclusive example, the fifth polymer layer 1600 is a polyimide layer. Formation and patterning of the fifth polymer layer 1600 can be similar to the formation and patterning of the first polymer layer 302 of FIG. 3. As shown, the fifth polymer layer 1600 is patterned to produce openings 1602A, 1602B that expose portions of the third RDL 1500A, 1500B, respectively.

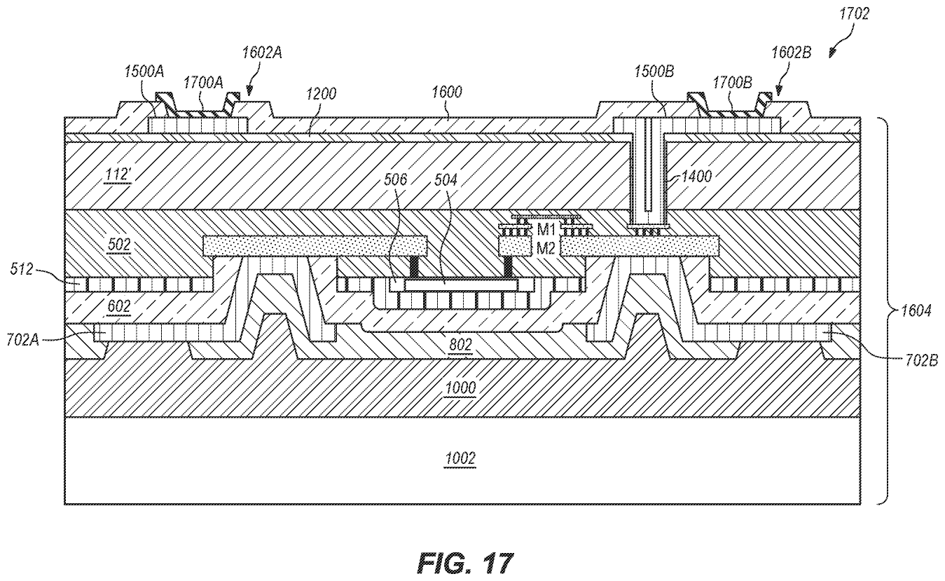

FIG. 17 illustrates the structure 1604 shown in FIG. 16 with the addition of a second UBM layer 1700A, 1700B in accordance with embodiments of the disclosure. In a non-limiting nonexclusive example, the second UBM layer 1700A, 1700B is a metal layer. The second UBM layer 1700A, 1700B may be formed on the third RDL 1500A, 1500B, respectively, by plating the second UBM layer 1700A on the third RDL 1500A that is exposed in the opening 1602A and on portions of the fifth polymer layer 1600, and by plating the second UBM layer 1700B on the third RDL 1500B that is exposed in the opening 1602B and on portions of the fifth polymer layer 1600. In certain embodiments, the second UBM layer 1700A, 1700B may be omitted.

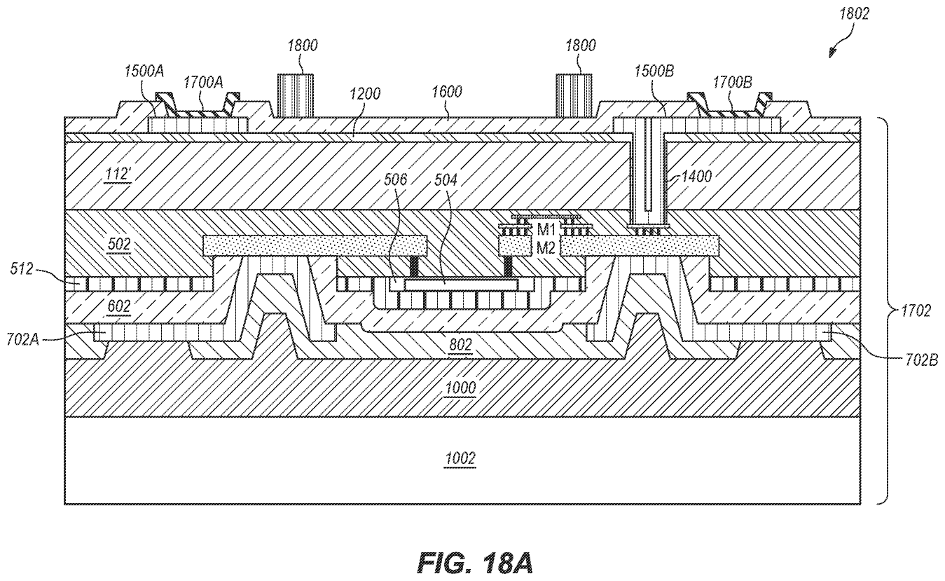

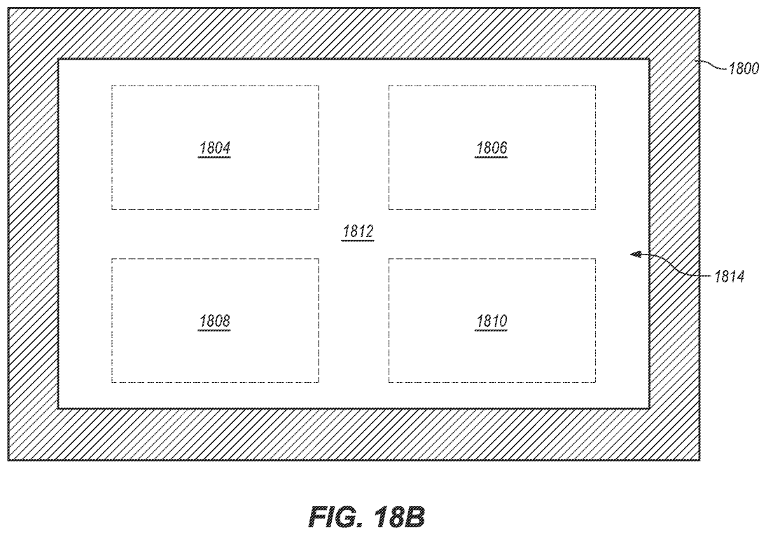

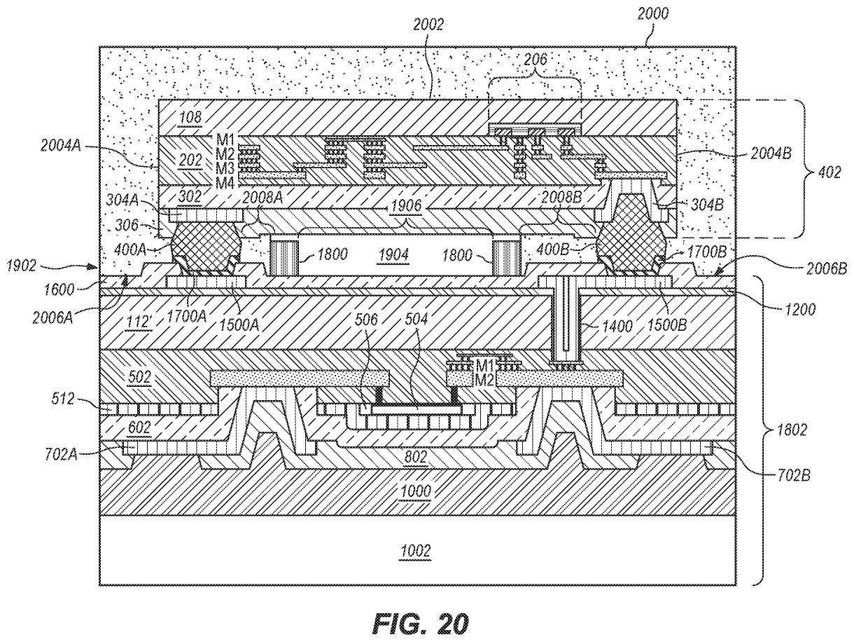

FIG. 18A illustrates the structure 1702 shown in FIG. 17 with the addition of a dam structure 1800 in accordance with embodiments of the disclosure. The dam structure 1800 is formed on the fifth polymer layer 1600 around a periphery of an area that will not be encapsulated. For example, the dam structure 1800 can be formed around the one or more MEMS RF switches in an array. As will be described in more detail in conjunction with FIG. 20, the dam structure 1800 is used to form an air pocket region between the MEMS wafer and the controller wafer in a completed vertically stacked structure.

In a non-limiting nonexclusive example, the dam structure 1800 is formed with a polymer, such as a polyimide. A sixth polymer layer (not shown) is formed over the fifth polymer layer 1600 and patterned to produce the dam structure 1800. The formation and patterning of the sixth polymer layer can be similar to the formation and patterning of the first polymer layer 302 shown in FIG. 3.

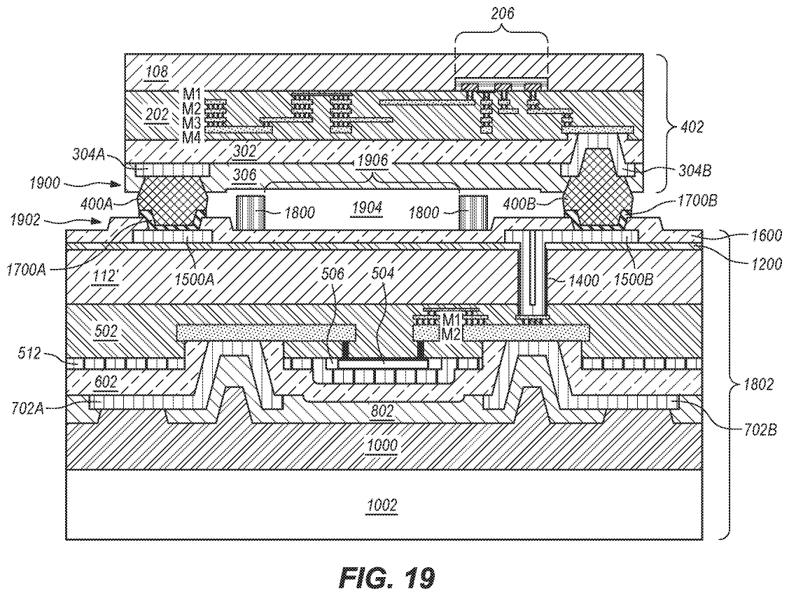

FIG. 18B illustrates a top view of the dam structure 1800 shown in FIG. 18A in accordance with embodiments of the disclosure. The dam structure 1800 forms a closed region 1812. The closed region 1812 surrounds MEMS RF switch 1804, MEMS RF switch 1806, MEMS RF switch 1808, and MEMS RF switch 1810 (e.g., an array of MEMS RF switches). The MEMS RF switches 1804, 1806, 1808, 1810 are shown in dashed lines because the MEMS RF switches 1804, 1806, 1808, 1810 reside in the MEMS cavity 506 (FIG. 18A), which is below the dam structure 1800. The dam structure 1800 and the closed region 1812 produce an air pocket region 1814 (1904 in FIG. 19) when the controller die and the MEMS die are stacked vertically. In one embodiment, the MEMS RF switches 1804, 1806, 1808, 1810 constitute all of the MEMS RF switches in the vertically stacked structure. In another embodiment, a dam structure may be formed around multiple arrays of MEMS RF switches in a vertically stacked structure. Although FIG. 18B shows four MEMS RF switches 1804, 1806, 1808, 1810, embodiments can include any number of MEMS RF switches.

FIG. 19 illustrates the structure 402 shown in FIG. 4 operably connected to the structure 1802 shown in FIG. 18 in accordance with embodiments of the disclosure. A frontside surface 1900 of the structure 402 is attached to a backside surface 1902 of the structure 1802 using the first electrical connectors 400A, 400B. In particular, the first electrical connectors 400A, 400B are physically and operably attached to the second UBM layers 1700A, 1700B of the structure 1802. Thus, the first electrical connectors 400A, 400B operably connect the controller wafer 300 to the MEMS wafer. In a non-limiting nonexclusive example, the first electrical connectors 400A, 400B are reflowed to operably connect the controller wafer to the structure 1802. Other processes can be used to operably connect the structure 402 to the structure 1802.

After the structure 402 is operably connected to the structure 1802, the dam structure 1800 creates an air pocket region 1904 in the space 1906. As shown and described in conjunction with FIG. 18B, the dam structure 1800 surrounds the area that will not be encapsulated to form the closed region 1810. The closed region 1810 produces the air pocket region 1904 between the frontside surface 1900 of the structure 402 and the backside surface 1902 of the structure 1802 where one or more MEMS RF switches reside.

FIG. 20 illustrates the structure 402 shown in FIG. 4 operably attached to the structure 1802 shown in FIG. 18 with the addition of an encapsulation layer 2000 in accordance with embodiments of the disclosure. The encapsulation layer 2000 can be the encapsulation layer 126 shown in FIG. 1. The encapsulation layer 2000 is formed over the structure 402 and portions of the backside surface 1902 of the structure 1802. In the example embodiment, the encapsulation layer 2000 is formed over a backside surface 2002 of the structure 402, over the vertical sides 2004A, 2004B of the structure 402, and over portions 2006A, 2006B of the backside surface 1902 of the structure 1802.

In a non-limiting nonexclusive example, the encapsulation layer 2000 is formed using an overmolding process. Because the overmolding process can be a high-pressure process, encapsulation material is pushed into the spaces 2008A, 2008B between the structure 402 and the structure 1802. The dam structure 1800 prevents the encapsulation material from passing into the space 1906. The space 1906 remains filled with air to form the air pocket region 1904 between the structure 402 and the structure 1802.

The air pocket region 1904 further electrically separates the MEMS device from the controller device. The air pocket region 1904 reduces the chances that the electric fields generated in the controller circuitry of the controller device will couple with the MEMS device. The air pocket region 1904 reduces the capacitive coupling between the controller device and the MEMS device.

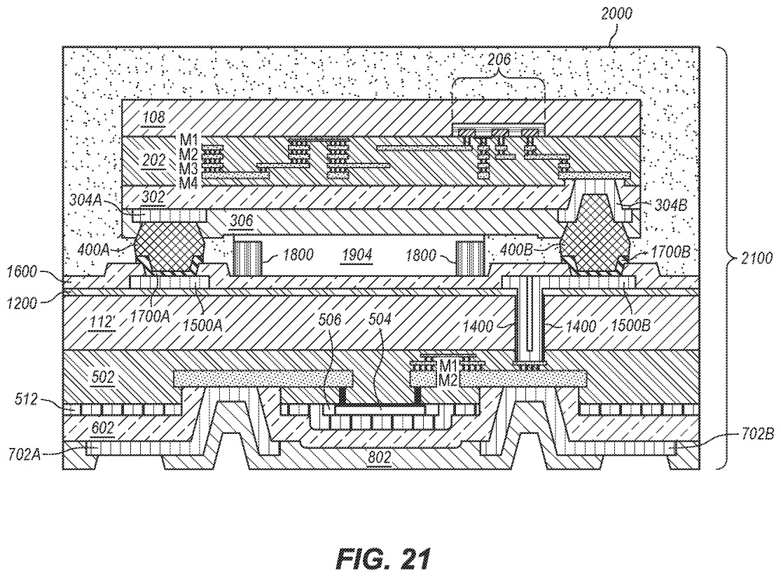

FIG. 21 illustrates a vertically stacked structure 2100 after the film 1000 and the carrier wafer 1002 shown in FIG. 20 are removed in accordance with embodiments of the disclosure. The film 1000 can be removed using a laser or a thermal release process. Removal of the film 1000 also removes the carrier wafer 1002.

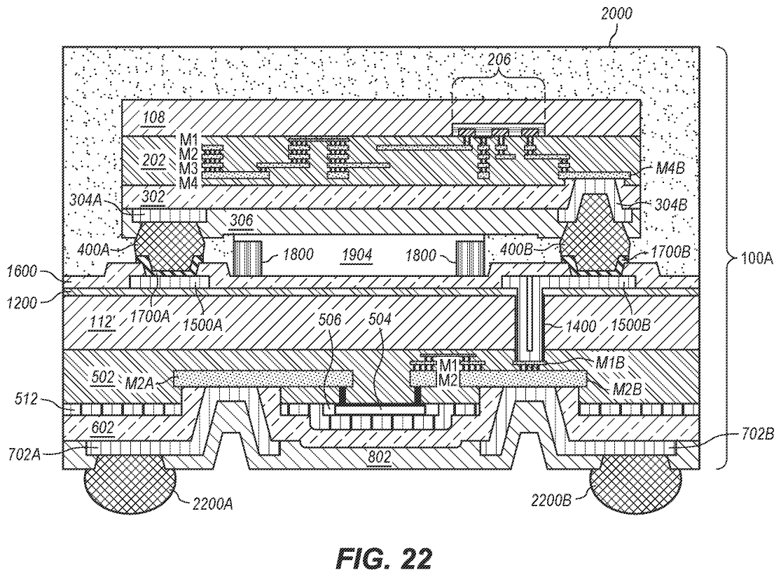

FIG. 22 illustrates a completed first version 100A first vertically stacked structure shown in FIG. 1 with the addition of second electrical connectors 2200A, 2200B in accordance with embodiments of the disclosure. The second electrical connectors 2200A, 2200B are the first and the second electrical connectors 122A, 122B, respectively shown in FIG. 1. The second electrical connectors 2200A, 2200B are formed on the second RDL 702A, 702B, respectively, of the MEMS wafer (e.g., MEMS wafer 700 shown in FIG. 8). The MEMS wafer and the controller wafer that include multiple first versions 100A of the first vertically stacked structure are then diced to produce individual first versions 100A of the first vertically stacked structure.

The second electrical connectors 2200A, 2200B are depicted as solder balls. However, the second electrical connectors 2200A, 2200B may be any suitable type of electrical connectors. In certain embodiments, a UBM layer can be formed over the second RDL 702A, 702B before the second electrical connectors 2200A, 2200B are formed to improve the bonding strength of the second electrical connectors 2200A, 2200B to the second RDL 702A, 702B.

The second electrical connectors 2200A, 2200B are used to operably connect the first version 100A of the first vertically stacked structure to external electrical devices. In the embodiment shown in FIG. 22, the second electrical connector 2200A is operably connected to the one or more MEMS RF switches 504 (e.g., FIG. 5) through the second RDL 702A and the conductive layer M2A. Accordingly, RF signals are transmitted between an external electrical device (e.g., an antenna) and the one or more MEMS RF switches 504 using the second electrical connector 2200A. Thus, the RF signals do not transmit in or do not transmit through the second substrate 112′ and do not transmit in or do not transmit through the first substrate 108.

The second electrical connector 2200B is used to transmit power and I/O signals to and between the MEMS die (e.g., MEMS die 104 in FIG. 1) and the controller die (e.g., controller die 102 in FIG. 1). Power signals are transmitted to the MEMS die using the second RDL 702B and the conductive layer M2B (e.g., FIG. 5). Power and I/O signals are transmitted to the controller die using the second RDL 702B, the conductive layer M2B, the conductive layer M1 B (e.g., FIG. 15), the third RDL 1500B (e.g., FIG. 15), the second UBM layer 1700B (e.g., FIG. 17), the first electrical connector 400B (e.g., FIG. 19), the first RDL 304B (e.g., FIG. 4), and the electrical connector M4B (e.g., FIG. 3).

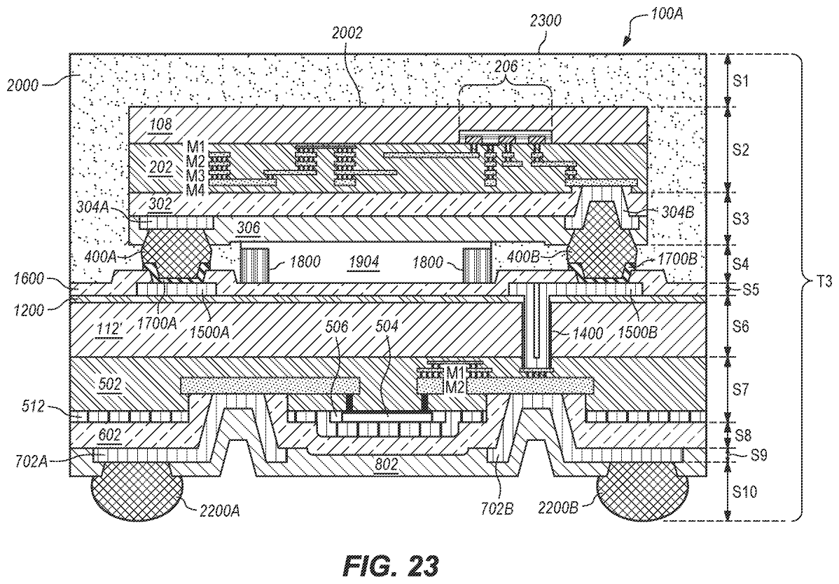

FIG. 23 illustrates example sections S1-S10 in the first version 100A of the first vertically stacked structure shown in FIG. 22 in accordance with embodiments of the disclosure. Non-limiting nonexclusive examples of the thicknesses of the sections S1-S10 are provided. Section S1 includes an upper portion of the encapsulation layer 2000 that is positioned between a backside surface 2300 of the first vertically stacked structure 100A and the backside surface 2002 of the structure 402. Section S1 has a thickness of approximately fifty (50) micrometers.

Section S2 includes portions of the encapsulation layer 2000, the first substrate 108, and the one or more first dielectric layers 202. Section S2 has a thickness of approximately fifty (50) micrometers.

Section S3 includes portions of the encapsulation layer 2000, the second polymer layer 306, the first polymer layer 302, the first RDL 304A, 304B, and portions of the first electrical connectors 400A, 400B. Section S3 has a thickness of approximately fifteen (15) micrometers.

Section S4 includes portions of the encapsulation layer 2000, portions of the first electrical connectors 400A, 400B, the dam structure 1800, the air pocket region 1904, the second UBM layers 1700A, 1700B, and portions of the fifth polymer layer 1600. Section S4 has a thickness of approximately fifty (50) micrometers.

Section S5 includes portions of the fifth polymer layer 1600, a portion of the third RDL 1500B, and the third RDL 1500A. Section S5 has a thickness of approximately ten (10) micrometers.

Section S6 includes portions of the third RDL 1500B, the fourth dielectric layer 1200, and the second substrate 112′. Section S6 has a thickness of approximately seventy-six (76) micrometers.

Section S7 includes the one or more second dielectric layers 502, a portion of the third RDL 1500B, the MEMS cavity 506, portions of the third polymer layer 602, portions of the second RDL 702A, 702B, and portions of the third dielectric layer 512. Section S7 has a thickness of approximately fourteen (14) micrometers.

Section S8 includes portions of the third polymer layer 602, portions of the second RDL 702A, 702B, portions of the third dielectric layer 512, and portions of the fourth polymer layer 802. Section S8 has a thickness of approximately seven (7) micrometers.

Section S9 includes portions of the second RDL 702A, 702B and portions of the fourth polymer layer 802. Section S9 has a thickness of approximately nine (9) micrometers.

Section S10 includes portions of the fourth polymer layer 802 and the second electrical connectors 2200A, 2200B. Section S10 has a thickness of approximately one hundred and seventy (170) micrometers. Adding the thicknesses of the sections S1-S10, the total thickness T3 of the first version 100A of the first vertically stacked structure is approximately four hundred and fifty-one (451) micrometers. In embodiments where the second substrate 112′ has a thickness of fifty (50) micrometers, the total thickness T3 of the first version 100A of the first vertically stacked structure is approximately four hundred and twenty-five (425) micrometers. In another non-limiting example, the total thickness T3 is less than or equal to four hundred and fifty (450) micrometers. In yet another non-limiting example, the total thickness T3 is less than four hundred and sixty (460) micrometers. One or more of the sections S1-S10 can have different thicknesses in other embodiments.

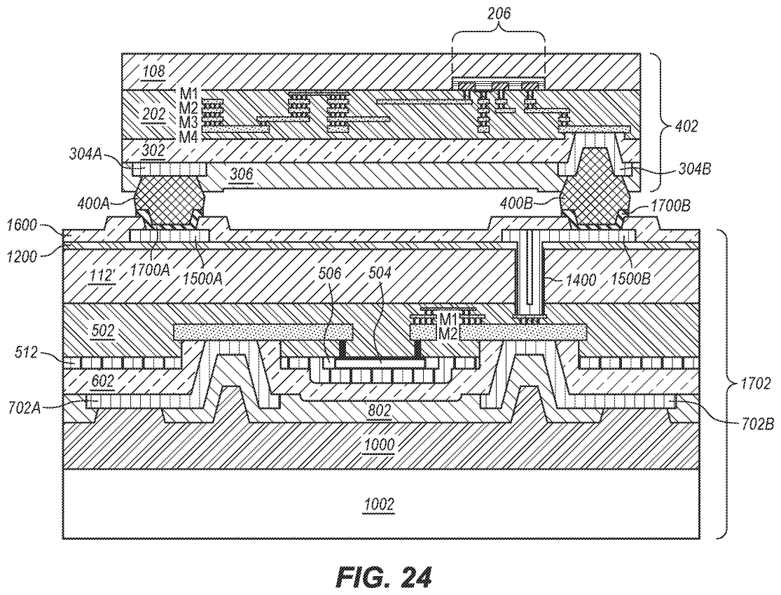

FIGS. 24-27 show another example method of fabricating the first vertically stacked structure 100 shown in FIG. 1. The method begins at FIG. 24. FIG. 24 illustrates the structure 402 shown in FIG. 4 operably connected to the structure 1702 shown in FIG. 17 in accordance with embodiments of the disclosure. Prior to FIG. 24, the processes shown in FIGS. 3, 4, and 6-17 have been performed. Since the process shown in FIG. 18 has not been performed, the dam structure 1800 is not formed over the fifth polymer layer 1600.

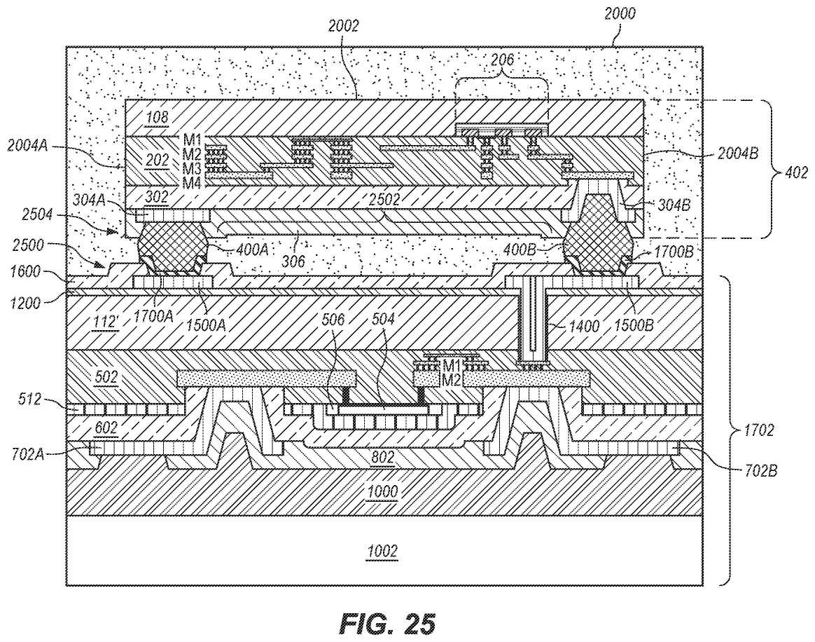

FIG. 25 illustrates the structure 402 operably connected to the structure 1702 as shown in FIG. 24 with the addition of the encapsulation layer 2000 in accordance with embodiments of the disclosure. The encapsulation layer 2000 is formed over the structure 402 and portions of the backside surface 2500 of the structure 1702. In the example embodiment, the encapsulation layer 2000 is formed over the backside surface 2002 of the structure 402, over the vertical sides 2004A, 2004B of the structure 402, and over the portions of the backside surface 2500 of the structure 1702.

Since the structure 1702 does not include the dam structure 1800 (FIG. 18), the encapsulation material is pushed into the space 2502 between the structure 402 and the structure 1702. In some instances, the encapsulation material fills the space 2502. As such, an air pocket region is not formed and the encapsulation material contacts both the frontside surface 2504 of the structure 402 and the backside surface 2500 of the structure 1702.

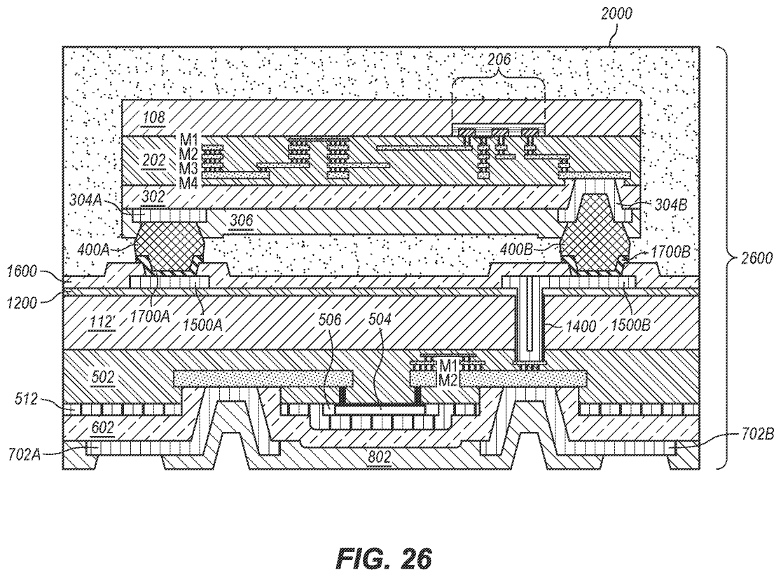

FIG. 26 illustrates a vertically stacked structure after the film 1000 and the carrier wafer 1002 shown in FIG. 25 are removed in accordance with embodiments of the disclosure. The film 1000 can be removed using a laser or a thermal release process. Removal of the film 1000 also removes the carrier wafer 1002.

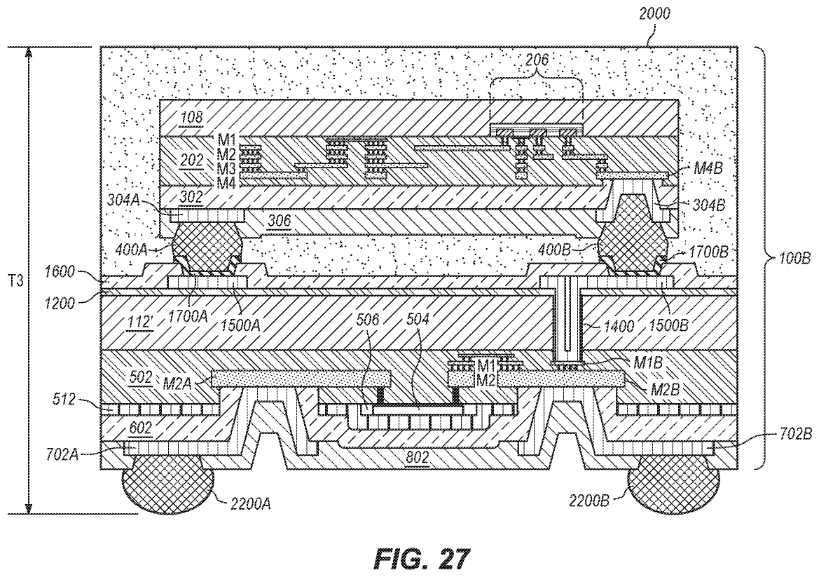

FIG. 27 illustrates a second version 1001B of the first vertically stacked structure shown in FIG. 1 with the addition of second electrical connectors 2200A, 2200B in accordance with embodiments of the disclosure.

Like FIG. 22, the second electrical connectors 2200A, 2200B are formed on the second RDL 702A, 702B, respectively, of the MEMS wafer (e.g., MEMS wafer 700 shown in FIG. 8). The MEMS wafer and the controller wafer that include multiple second versions 1001B of the first vertically stacked structure are then diced to produce individual second versions 100B of the first vertically stacked structure. A thickness T3 of the second version 1001B can equal or substantially equal the thickness T2 of the first version 100A shown in FIG. 23.

The second electrical connectors 2200A, 2200B are depicted as solder balls. However, the second electrical connectors 2200A, 2200B may be any suitable type of electrical connectors. In certain embodiments, a UBM layer can be formed over the second RDL 702A, 702B before the second electrical connectors 2200A, 2200B are formed to improve the bonding strength of the second electrical connectors 2200A, 2200B to the second RDL 702A, 702B.

The second electrical connectors 2200A, 2200B are used to operably connect the second version 100B of the first vertically stacked structure to external electrical devices. In the embodiment shown in FIG. 27, the second electrical connector 2200A is operably (e.g., electrically) connected to the one or more MEMS RF switches 504 (FIG. 5) through the second RDL 702A and the conductive layer M2A. Accordingly, RF signals are transmitted between an external electrical device (e.g., an antenna) and the one or more MEMS RF switches 504 using the second electrical connector 2200A.

The second electrical connector 2200B is used to transmit power and I/O signals to and between the MEMS die (e.g., MEMS die 104 in FIG. 1) and the controller die (e.g., controller die 102 in FIG. 1). Power signals are transmitted to the MEMS die using the second RDL 702B and the conductive layer M2B (e.g., FIG. 5). Power and I/O signals are transmitted to the controller die using the second RDL 702B, the conductive layer M2B, the conductive layer M1 B (e.g., FIG. 15), the third RDL 1500B (e.g., FIG. 15), the second UBM layer 1700B (e.g., FIG. 17), the first electrical connector 400B (e.g., FIG. 19), the first RDL 304B (e.g., FIG. 4), and the electrical connector M4B (e.g., FIG. 3).

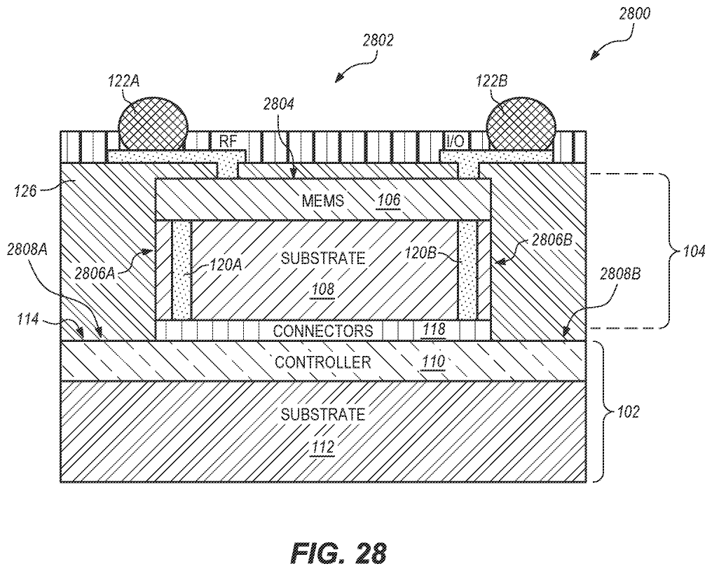

Vertically stacked structures that include the controller die and the MEMS die can have different arrangements in other embodiments. FIGS. 28-31B illustrate different arrangements of a vertically stacked structure. Similar processes to the processes shown in FIG. 3 and in FIG. 4 can be performed for the controller die in all of the different arrangements. Similar processes to the processes shown in FIGS. 6-18 or in FIGS. 6-17 may be performed for the MEMS die in all of the different arrangements. Similar processes to the processes shown in FIGS. 20-22 can be performed to operably connect the controller die to the MEMS die and to complete the formation of the vertically stacked structures. Thus, the different arrangements can include or omit the dam structure and the air pocket region. The different arrangements depict the MEMS die and the controller die in different orientations relative to one another.

FIG. 28 illustrates a second vertically stacked structure 2800 that includes the controller die 102 and the MEMS die 104 shown in FIG. 1 in accordance with embodiments of the disclosure. The second vertically stacked structure 2800 is similar to the first vertically stacked structure shown in FIG. 1 except that the orientation of the second vertically stacked structure 2800 is flipped when compared to the orientation of the first vertically stacked structure 100. The first electrical connector 122A and the second electrical connector 122B are attached at a top surface 2802 of the second vertically stacked structure 2800. In FIG. 1, the first electrical connector 122A and the second electrical connector 122B are attached at a bottom surface of the first vertically stacked structure 100.

The encapsulation layer 126 is formed over the MEMS die 104 and the controller die 102. The encapsulation layer 126 can contact the frontside surface 2804 of the MEMS die 104, the side edges 2806A, 2806B of the MEMS die 104, and exposed portions 2808A, 2808B of the frontside surface 114 of the controller die 102.

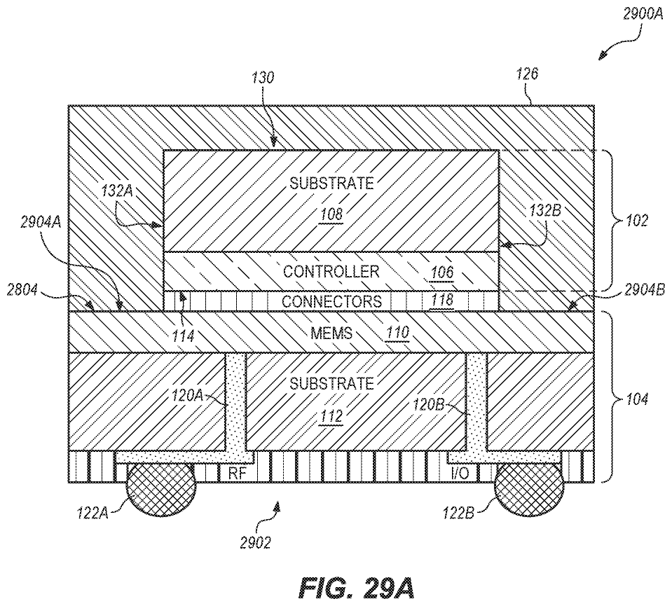

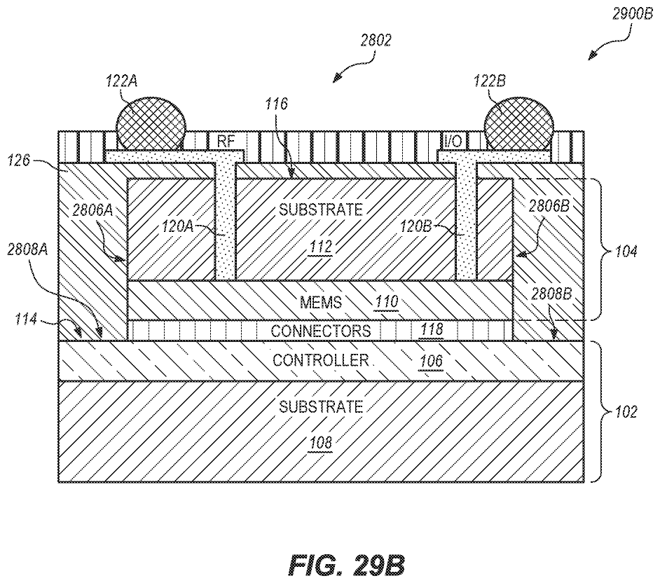

FIG. 29A illustrates a third vertically stacked structure 2900A that includes the controller die 102 and the MEMS die 104 shown in FIG. 1 in accordance with embodiments of the disclosure. The third vertically stacked structure 2900A is oriented such that the first electrical connector 122A and the second electrical connector 122B are attached at a bottom surface 2902 of the third vertically stacked structure 2900A. A frontside surface 114 of the controller die 102 is operably connected to a frontside surface 2804 of the MEMS die 104 using the connector layer 118. The first TSV 120A and the second TSV 120B are formed through the second substrate 112.

The encapsulation layer 126 is formed over the controller die 102 and the MEMS die 104. The encapsulation layer 126 can contact the backside surface 130 of the controller die 102, the side edges 132A, 132B of the controller die 102, and exposed portions 2904A, 2904B of the frontside surface 2804 of the MEMS die 104.

FIG. 29B illustrates a fourth vertically stacked structure 2900B that includes the controller die 102 and the MEMS die 104 shown in FIG. 1 in accordance with embodiments of the disclosure. The fourth vertically stacked structure 2900B is oriented such that the first electrical connector 122A and the second electrical connector 122B are attached at the top surface 2802 of the fourth vertically stacked structure 2900B. The first TSV 120A and the second TSV 120B are formed through the second substrate 112.

The encapsulation layer 126 is formed over the MEMS die 104 and the controller die 102. The encapsulation layer 126 can contact the backside surface 116 of the MEMS die 104, the side edges 2806A, 2806B of the MEMS die 104, and exposed portions 2808A, 2808B of the frontside surface 114 of the controller die 102.

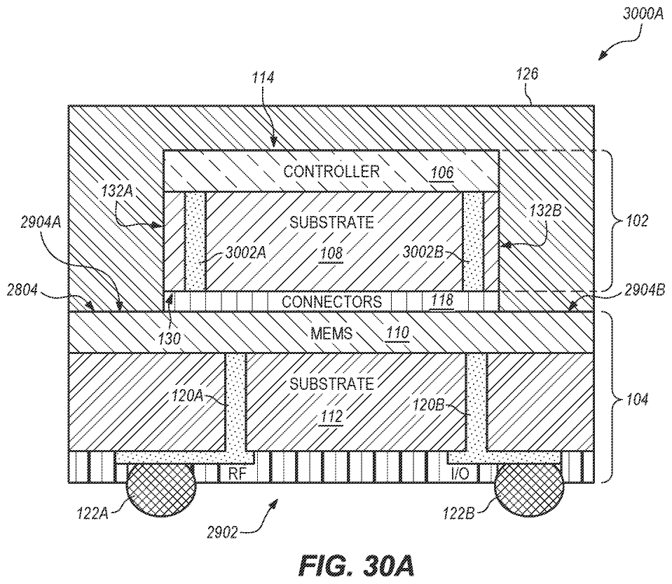

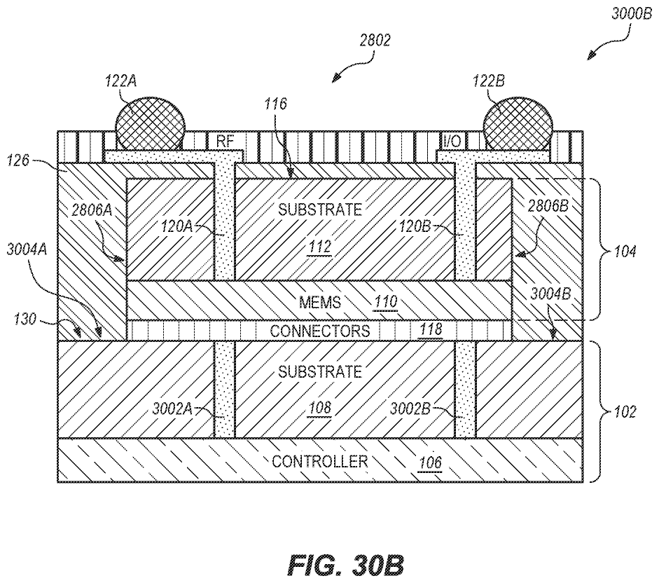

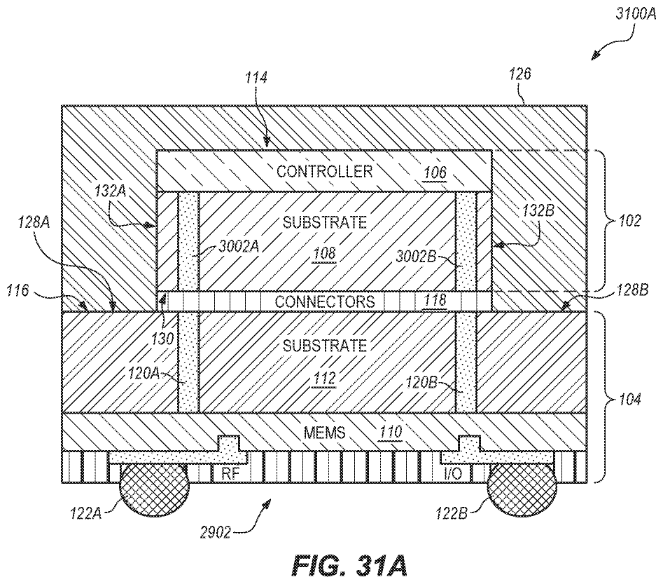

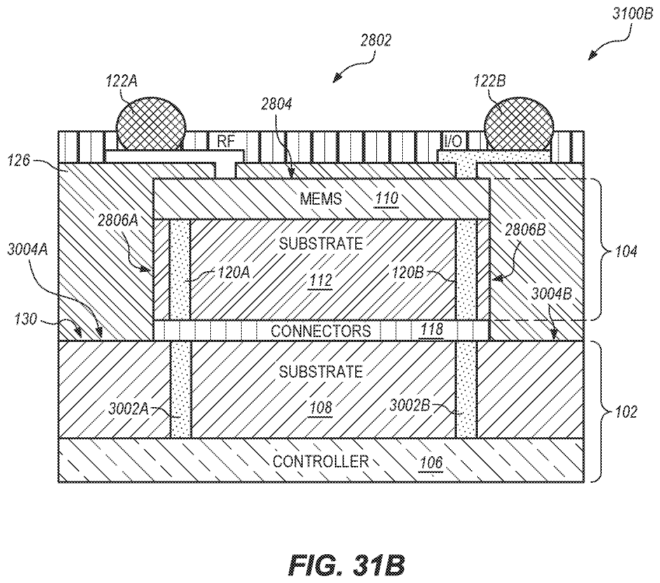

The arrangements shown in FIGS. 30A-31B include TSVs formed in the first substrate 108 in addition to the first TSV 120A and the second TSV 120B formed in the second substrate 112. The process used to form the TSVs in the first substrate 108 can be similar to the process used to form the first TSV 120A and the second TSV 120B in the second substrate 112.

FIG. 30A illustrates a fifth vertically stacked structure 3000A that includes the controller die 102 and the MEMS die 104 shown in FIG. 1 in accordance with embodiments of the disclosure. The fifth vertically stacked structure 3000A is oriented such that the first electrical connector 122A and the second electrical connector 122B are attached at the bottom surface 2902 of the fifth vertically stacked structure 3000A. The backside surface 130 of the controller die 102 is operably connected to the frontside surface 2804 of the MEMS die 104 using the connector layer 118. The first TSV 120A and the second TSV 120B are formed through the second substrate 112.

TSVs 3002A, 3002B are also formed through the first substrate 108. The TSVs 3002A, 3002B are used to operably connect the controller circuitry 106 to the first electrical connector 122A and to the second electrical connector 122B using the connector layer 118 and the first TSV 120A and the second TSV 120B. In a non-limiting nonexclusive example, the TSVs 3002A, 3002B can operably connect the conductive layer M1 (e.g., FIG. 2) to an RDL layer (not shown) or to a UBM layer (not shown) in the controller die 102 that is operably connected to the first electrical connectors 400A, 400B (e.g., FIG. 19).

The encapsulation layer 126 is formed over the controller die 102 and the MEMS die 104. The encapsulation layer 126 can contact the frontside surface 114 of the controller die 102, the side edges 132A, 132B of the controller die 102, and the exposed portions 2904A, 2904B of the frontside surface 2804 of the MEMS die 104.

FIG. 30B illustrates a sixth vertically stacked structure 3000B that includes the controller die 102 and the MEMS die 104 shown in FIG. 1 in accordance with embodiments of the disclosure. The sixth vertically stacked structure 3000B is oriented such that the first electrical connector 122A and the second electrical connector 122B are attached at the top surface 2802 of the sixth vertically stacked structure 3000B.

The first TSV 120A and the second TSV 120B are formed through the second substrate 112. TSVs 3002A, 3002B are formed through the first substrate 108. The encapsulation layer 126 is formed over the MEMS die 104 and the controller die 102. The encapsulation layer 126 can contact the backside surface 116 of the MEMS die 104, the side edges 2806A, 2806B of the MEMS die 104, and the exposed portions 3004A, 3004B of the backside surface 130 of the controller die 102.

FIG. 31A illustrates a seventh vertically stacked structure 3100A that includes the controller die 102 and the MEMS die 104 shown in FIG. 1 in accordance with embodiments of the disclosure. The seventh vertically stacked structure 3100A is oriented such that the first electrical connector 122A and the second electrical connector 122B are attached at the bottom surface 2902 of the seventh vertically stacked structure 3100A. A backside surface 130 of the controller die 102 is operably connected to a backside surface 116 of the MEMS die 104 using connector layer 118.

The first TSV 120A and the second TSV 120B are formed through the second substrate 112. TSVs 3002A, 3002B are formed through the first substrate 108. The encapsulation layer 126 is formed over the controller die 102 and the MEMS die 104. The encapsulation layer 126 can contact the frontside surface 114 of the controller die 102, the side edges 132A, 132B of the controller die 102, and the exposed portions 128A, 128B of the backside surface 116 of the MEMS die 104.

FIG. 31B illustrates an eighth vertically stacked structure 3100B that includes the controller die 102 and the MEMS die 104 shown in FIG. 1 in accordance with embodiments of the disclosure. The eighth vertically stacked structure 31001B is oriented such that the first electrical connector 122A and the second electrical connector 122B are attached at a top surface 2802 of the eighth vertically stacked structure 31001B.

The first TSV 120A and the second TSV 120B are formed through the second substrate 112. TSVs 3002A, 3002B are formed through the first substrate 108. The encapsulation layer 126 is formed over the MEMS die 104 and the controller die 102. The encapsulation layer 126 can contact the frontside surface 2804 of the MEMS die 104, the side edges 2806A, 2806B of the MEMS die 104, and the exposed portions 3004A, 3004B of the backside surface 130 of the controller die 102.

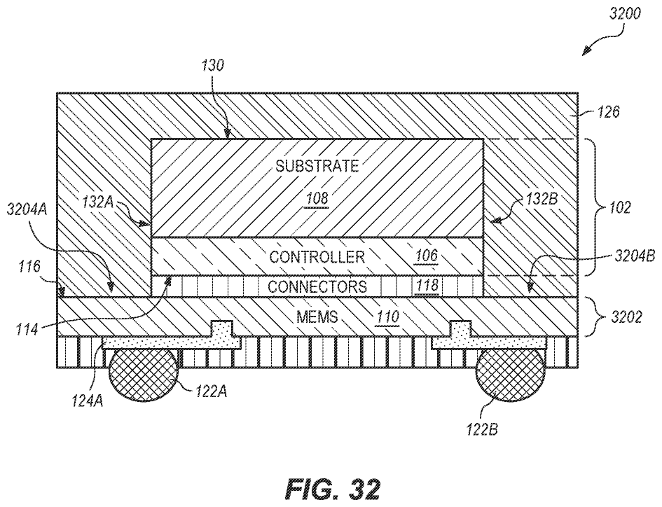

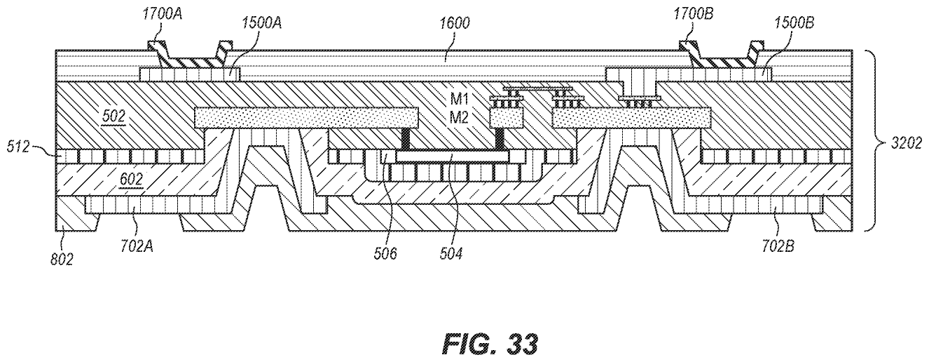

FIG. 32 illustrates a ninth vertically stacked structure 3200 that includes the controller die 102 shown in FIG. 1 and an alternate MEMS die 3202 in accordance with embodiments of the disclosure. Like FIG. 1, the controller die 102 includes controller circuitry 106 formed in and/or over a first substrate 108. The MEMS die 3202 includes MEMS circuitry 110 formed in and/or over one or more dielectric layers (one or more second dielectric layers 502 in FIG. 33).

A frontside surface 114 of the controller die 102 is operably connected to a backside surface 116 of the MEMS die 3202 using the connector layer 118.

RF signals are input and output from the MEMS circuitry 110 to another electronic device (not shown), such as an antenna, using first electrical connector 122A and first contact pad 124A. Power signal and I/O signals are input and output to the MEMS circuitry 110 and/or to the controller circuitry 106 using second electrical connector 122B and second contact pad 124B. In FIG. 32, the first electrical connector 122A and the second electrical connector 122B are shown as solder balls, but other embodiments can use a different type of electrical connector.

The encapsulation layer 126 is formed over the controller die 102 and the MEMS die 104. The encapsulation layer 126 can contact the backside surface 130 of the controller die 102, the side edges 132A, 132B of the controller die 102, and exposed portions 3204A, 3204B of the backside surface 116 of the MEMS die 3202.

FIG. 33 illustrates an example of the alternate MEMS die 3202 shown in FIG. 32 in accordance with embodiments of the disclosure. Essentially, the MEMS die 3202 is the same as the MEMS wafer shown in FIG. 17 with the film 1000, the carrier wafer 1002, the fourth dielectric layer 1200, and all of the second substrate 112′ removed. The entire second substrate 112 is thinned (e.g., FIG. 11) to remove all of the second substrate 112. The fourth dielectric layer 1200 may be omitted from the MEMS die 3202 as shown, or the fourth dielectric layer 1200 can be formed over the one or more second dielectric layers 502. The film 1000 and the carrier wafer 1002 are typically attached to the frontside of the MEMS wafer after the third polymer layer 602, the second RDL 702A, 702B and the fourth polymer layer 802 have been formed on the frontside of the MEMS wafer prior to thinning the second substrate 112 as in FIG. 10. The film 1000 and the carrier wafer 1002 are removed once the encapsulation layer 126 (FIG. 32) is formed.

As should be appreciated, FIGS. 1-33 are described for purposes of illustrating example methods and systems and is not intended to limit the disclosure to a particular sequence of fabrication operations or a particular combination of components in vertically stacked structures.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

What is claimed is:

1. A vertically stacked structure, comprising:
a microelectromechanical (MEMS) die operably connected to a controller die using a first electrical connector, wherein:
the controller die comprises controller circuitry formed in and over a first substrate, the controller circuitry operably connected to the first connector;
the MEMS die comprises MEMS circuitry formed in or over a second substrate, the MEMS circuitry operably connected to the first electrical connector; and
the first electrical connector is operable to transmit a control signal from the controller circuitry to the MEMS circuitry; and
a second electrical connector operably connected to the MEMS circuitry, the second electrical connector operable to transmit a radio frequency (RF) signal from the MEMS circuitry and out of the vertically stacked structure, wherein the RF signal is not routed through the first substrate of the controller die or the second substrate of the MEMS die.

2. The vertically stacked structure of claim 1, wherein:
the MEMS circuitry is at a frontside surface of the MEMS die;
the first electrical connector is located at a backside surface of the MEMS die; and
the MEMS circuitry is operably connected to the first connector through a through silicon via.

3. The vertically stacked structure of claim 1, further comprising an encapsulation layer formed over a backside surface of the controller die, sides of the controller die, and exposed portions of a bottom surface of the MEMS die.

4. The vertically stacked structure of claim 3, further comprising:
a dam structure surrounding a perimeter of a space between the MEMS die and the controller die, the dam structure forming a closed region that creates an air pocket region; and
an encapsulation material around the perimeter of the space.

5. The vertically stacked structure of claim 1, wherein:
the MEMS circuitry comprises a MEMS RF switch that is formed in a MEMS cavity; and
the MEMS cavity is encapsulated by dielectric layers.

6. The vertically stacked structure of claim 5, wherein:
the MEMS circuitry comprises a conductive layer operably connected to the MEMS RF switch; and
the MEMS die comprises a redistribution layer operably connected between the conductive layer and the second electrical connector.

7. The vertically stacked structure of claim 1, wherein:
the controller circuitry comprises:
a conductive layer in a dielectric layer; and
an active device operably connected to the conductive layer; and
the controller die comprises a redistribution layer operably connected between the conductive layer and the first electrical connector.

8. The vertically stacked structure of claim 1, wherein:
the MEMS circuitry comprises a conductive layer in a dielectric layer; and
the MEMS die comprises:
a redistribution layer operably connected between the conductive layer and a third electrical connector, the third electrical connector operable to receive a power signal; and
a through silicon via operably connecting the conductive layer to the first electrical connector.

9. The vertically stacked structure of claim 1, further comprising encapsulation material in a space between the MEMS die and the controller die.

10. The vertically stacked structure of claim 1, wherein:
the second substrate comprises one of a high resistivity silicon substrate or a first dielectric substrate; and
the first substrate comprises one of a low resistivity silicon substrate, a high resistivity substrate, or a second dielectric substrate.

11. The vertically stacked structure of claim 1, wherein the second substrate comprises one or more dielectric layers with the MEMS circuitry disposed in and over the one or more dielectric layers.

12. A vertically stacked structure, comprising:
a microelectromechanical (MEMS) die;
a controller die, wherein a backside surface of the MEMS die is operably connected to a frontside surface of the controller die through a first electrical connector, wherein:
the controller die comprises a first substrate and controller circuitry, the controller circuitry operably connected to the first electrical connector to enable the controller circuitry to transmit control signal to the first electrical connector;
the MEMS die comprises a second substrate and a MEMS radio frequency (RF) switch, the MEMS RF switch operably connected to the first electrical connector to enable the MEMS RF switch to receive the control signal;
an air pocket region resides in a space between the backside surface of the MEMS die and the frontside surface of the controller die; and
a second electrical connector is operably connected to the MEMS RF switch, the second electrical connector operable to transmit an RF signal from the MEMS RF switch and out of the vertically stacked structure, wherein the RF signal remains at a frontside surface of the MEMS die.

13. The vertically stacked structure of claim 12, further comprising:
a dam structure surrounding the space, the dam structure forming a closed region that creates the air pocket region; and
an encapsulation material surrounding the space.

14. The vertically stacked structure of claim 13, wherein the dam structure is formed with a polymer material.

15. The vertically stacked structure of claim 12,
the second substrate comprises one of a high resistivity silicon substrate or a first dielectric substrate; and
the first substrate comprises one of a low resistivity silicon substrate, a high resistivity substrate, or a second dielectric substrate.

16. The vertically stacked structure of claim 12, wherein:
the second substrate comprises one or more dielectric layers; and
the MEMS RF switch is disposed in a MEMS cavity that is encapsulated by at least one dielectric layer in the one or more dielectric layers.

17. The vertically stacked structure of claim 12, wherein:
the MEMS die comprises a redistribution layer operably connected between a conductive layer and the second electrical connector; and
the MEMS RF switch is operably connected to the conductive layer.

18. The vertically stacked structure of claim 12, wherein:
the controller circuitry comprises:
a conductive layer in a dielectric layer; and
an active device operably connected to the conductive layer; and
the controller die comprises a redistribution layer operably connected between the conductive layer and the first electrical connector.

19. The vertically stacked structure of claim 12, wherein a thickness of the vertically stacked structure is less than four hundred and sixty micrometers.

20. A method, comprising:
forming a dam structure over a backside surface of a microelectromechanical (MEMS) die;
physically and operably connecting the backside surface of the MEMS die to a frontside surface of a controller die using a first electrical connector, wherein:
the controller die comprises a first substrate and controller circuitry, the controller circuitry operably connected to the first electrical connector to enable the first electrical connector to transmit a control signal to the MEMS die;
the MEMS die comprises a second substrate and a MEMS radio frequency (RF) switch, the MEMS RF switch operably connected to the first electrical connector to enable the MEMS RF switch to receive the control signal from the first electrical connector; and
the dam structure surrounds a space between the frontside surface of the controller die and the backside surface of the MEMS die to create an air pocket region;
forming an encapsulation layer over a backside surface of the controller layer and over portions of the backside surface of the MEMS die; and
operably connecting the MEMS RF switch to a second electrical connector to enable the second electrical connector to transmit an RF signal from the MEMS RF switch and out of the vertically stacked structure without routing the RF signal through the first substrate of the controller die or the second substrate of the MEMS die.
